(19) United States
(12) Patent Application Publication
(10) Pub. No.: US 2026/0146360 A1
(43) Pub. Date: May 28, 2026

(54) Controlling Silicon Carbide Crystal Growth with Baffles

(71) Applicant: Wolfspeed, Inc., Durham, NC (US)

(72) Inventors: Adrian Roger Powell, Cary, NC (US); Valeri Fedorovich Tsvetkov, Durham, NC (US); Caleb Andrew Kent, Durham, NC (US); Brian Bennett Haidet, Raleigh, NC (US); Steven Herbert Griffiths, Morrisville, NC (US); Benjamin Lefler Layne, Durham, NC (US); Jonathan Karl Meyers, Cary, NC (US); Yuri I. Khlebnikov, Raleigh, NC (US); Varad Rajan Sakhalkar, Cary, NC (US)

(21) Appl. No.: 18/962,454

(22) Filed: Nov. 27, 2024

(51) Int. Cl. C30B 23/00; C30B 23/02; C30B 29/36; C30B 35/00

(52) U.S. Cl. CPC C30B 23/005; C30B 23/025; C30B 29/36; C30B 35/002

(57) ABSTRACT

Crystal growth systems with a baffle are provided. In one example, a crystal growth system for growing crystalline material, the crystalline material including silicon carbide, includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes one or more baffles within the crystal growth chamber and spaced apart from the source material. The one or more baffles include one or more apertures defined through the one or more baffles. The baffle includes a long dimension that is non-perpendicular to the growth surface of the seed crystal.

### FIELD

The present disclosure relates generally to crystal growth systems, such as silicon carbide crystal growth systems for growing crystalline silicon carbide semiconductor workpieces for fabrication of semiconductor devices.

### BACKGROUND

Semiconductor devices, including power semiconductor devices based on wide bandgap materials, may be formed on a semiconductor wafer as part of a semiconductor fabrication process. Single crystal silicon carbide (SiC) has proven to be a very useful wafer material in the manufacture of such semiconductor devices. Due to its physical strength and excellent resistance to many chemicals, silicon carbide may be used to fabricate very robust substrates adapted for use in the semiconductor industry. Silicon carbide has excellent electrical properties, including radiation hardness, high breakdown field, a relatively wide band gap, high saturated electron drift velocity, high-temperature operation, and absorption and emission of high-energy photons in the blue, violet, and ultraviolet regions of the optical spectrum.

### SUMMARY

Aspects and advantages of embodiments of the present disclosure will be set forth in part in the following description, or can be learned from the description, or can be learned through practice of the embodiments.

In an aspect, the present disclosure provides an example crystal growth system for growing crystalline material, the crystalline material including silicon carbide. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes one or more baffles within the crystal growth chamber and spaced apart from the source material. The one or more baffles include one or more apertures defined through the one or more baffles. The baffle includes a long dimension that is non-perpendicular to the growth surface of the seed crystal.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle within the crystal growth chamber and spaced apart from the source material, wherein the baffle comprises a composite shaped structure.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle within the crystal growth chamber and spaced apart from the source material. The baffle has a shape configured to provide asymmetric vapor transport from the source material to the silicon carbide seed crystal.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle including one or more tubular structures within the crystal growth chamber and spaced apart from the source material.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle within the crystal growth chamber and spaced apart from the source material. The baffle includes a first baffle structure and a second baffle structure spaced apart from the first baffle structure.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle within the crystal growth chamber and spaced apart from the source material. The baffle includes one or more recessed cavities.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle in a vapor transport path between the source material and the seed crystal and spaced apart from the source material. The baffle is, at least in part, graphite. At least a portion of the baffle has a porosity of about 70% or greater.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a sublimation system having a baffle structure according to example embodiments of the present disclosure;

FIG. 2 depicts a sublimation system having a baffle structure according to example embodiments of the present disclosure;

FIG. 3 depicts a sublimation system having a baffle structure according to example embodiments of the present disclosure;

FIGS. 4A-44C depict an example crystal growth system with various baffle structures according to example embodiments of the present disclosure.

FIGS. 45A and 45B depict example crystal growth systems having a baffle structure according to example embodiments of the present disclosure.

FIGS. 46A, 46B, 46C, and 46D depict example crystal growth systems having a baffle structure according to example embodiments of the present disclosure.

FIGS. 47A and 47B depict example crystal growth systems having a baffle structure according to example embodiments of the present disclosure.

FIGS. 48A and 48B depict example crystal growth systems having a baffle structure according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Example aspects of the present disclosure are directed to crystal growth systems (e.g., silicon carbide crystal growth systems) with a baffle structure. Silicon carbide crystalline material may be produced using various seeded sublimation crystal growth processes. In some example silicon carbide crystal growth processes, a seed crystal and a source material are arranged in a reaction crucible which is then heated to a sublimation temperature of the source material. By controlling heating of the reaction crucible, a thermal gradient is developed between the sublimating source material and the cooler seed crystal. As a result of the thermal gradient, source material in a vapor phase is transported onto the seed crystal where it is deposited to grow a solid bulk crystalline boule. This type of sublimation crystal growth process is commonly referred to as a physical vapor transport (PVT) process.

In some crystal growth systems and deposition systems, a sublimating source material is open to the seed crystal. That is, vapor flux and radiation are unobstructed by a physical barrier within a reaction crucible. This may impact control over the thermal gradient and/or chemical environment established by the crystal growth system, which in turn may impact crystal growth parameters (e.g., growth rate, concentration of species, etc.) and crystallization (e.g., defect formation, stress in the crystal lattice, etc.). Crystal growth process parameters (e.g., PVT crystal growth process parameters) are driven through thermodynamic and kinetic factors. As such, the ability to tailor the thermal gradient, transport of vapor (e.g., kinetic factors), and/or chemical environments to a particular crystal growth process, such as a PVT crystal growth process, would be useful.

According to example aspects of the present disclosure, one or more baffles may be used in crystal growth systems and deposition systems (e.g., epitaxial reactors), such as silicon carbide crystal growth sublimation systems to accommodate the transport (e.g., kinetic actors) of source material vapor while enhancing control over radiation, thermal gradients and/or chemical environment. For instance, in some examples, a baffle may accommodate a transport of vapor (e.g., source material vapor) while providing a physical separation of chemical and/or radiation between a sublimating source material and a seed crystal experiencing deposition at a growth front. As used herein, the term

Accordingly, aspects of the present disclosure are directed to a crystal growth system for growing silicon carbide crystalline material. The crystal growth system includes a seed holder configured to hold a silicon carbide seed crystal. The seed crystal provides a growth surface for growth of the silicon carbide crystalline material. The crystal growth system includes a crucible defining a crystal growth chamber. The crystal growth system includes a silicon carbide vapor source material. The crystal growth system includes a baffle within the crystal growth chamber that is spaced apart from the silicon carbide vapor source material.

In some embodiments, the baffle includes a porous material, such as porous graphite. In some examples, at least a portion of the baffle has a porosity of greater than about 50% by volume, such as greater than about 70% by volume, such as greater than 80% by volume. Porosity by volume expressed as a percentage refers to the percentage of the volume of voids in the baffle relative to the total volume of the material. In some embodiments, the baffle has a porosity in a range of about 50% to about 97%, such as about 80% to about 97%, such as about 85% to about 97%.

In some embodiments, the baffle includes one or more apertures defined through a thickness of the baffle. As used herein, an “aperture” is a defined opening, space, perforation, hole, or void in a structure that extends from one exterior surface of a structure to another exterior surface of the structure. In some embodiments, each of the one or more apertures has a largest dimension (e.g., diameter, width) that is about 20% or less than a width of the crystal growth chamber, such as about 15% or less, such as about 10% or less, such as about 5% or less. In some embodiments, each of the one or more apertures provides a path through the baffle for transport of vapor from the silicon carbide source material to the seed crystal without having significant crystal growth formation in the aperture.

In some embodiments, the baffle has a long dimension that is generally non-perpendicular to the growth surface of the seed crystal. In some embodiments, the baffle has a thickness in a direction of vapor transport through the baffle. In some embodiments, the baffle has a long dimension that is at least 5 times greater than the thickness, such as at least 10 times greater, such as at least 20 times greater, such as at least 50 times greater, such as in a range of about 5 times greater to about 50 times greater, such as in a range of about 10 times greater to about 50 times greater, such as in a range of about 10 times greater to about 20 times greater. In some embodiments, the baffle has a thickness in a range of about 0.5 mm to about 25 mm, such as about 2 mm to about 12 mm, such as about 2 mm to about 8 mm.

As used herein, the “width” or “width dimension” refers to a dimension of a baffle, an aperture, or other structure that runs in a plane that is perpendicular to the transport direction of vapor to the crystal growth system. The “long dimension” of a baffle, an aperture, or other structure refers to the longest dimension (e.g., greatest in magnitude) of the structure.

In some examples, the one or more apertures include a plurality of holes defined through the baffle. In some examples, the one or more apertures include an annular aperture defined through a thickness of the baffle. In some examples, a vapor transport direction through the one or more apertures is in a non-perpendicular direction relative to the growth surface of the seed crystal.

In some examples, the baffle is spaced apart from the seed holder and is not coupled to the seed holder. In some examples, the baffle is coupled to a side wall of the crucible. In some examples, a width or diameter of the aperture is in a range of about 2 mm to about 10 mm, such as about 3 mm to about 8 mm, such as about 4 mm to about 6 mm.

In some examples, the one or more apertures are arranged in the baffle to provide for non-uniform vapor transport from the source material to the seed crystal. As used herein, a baffle provides non-uniform vapor transport when vapor is transported through a first portion of the baffle at a first rate and is transported through a second portion of the baffle at a second rate. The first rate is different from the second rate. For instance, a baffle may include a first portion with one or more apertures that transports vapor at a first rate. The baffle may include a second portion without apertures that transports vapor at a second rate. In some embodiments, a first portion of the baffle may have a first porosity and a second portion of the baffle may have a second porosity. The second porosity may be different than the first porosity. Vapor may be transported through the first portion at a first rate and may be transported through the second portion at a second rate that is different from the first rate.

In some examples, the one or more apertures are arranged in the baffle to provide for asymmetric vapor transport from the source material to the seed crystal. Asymmetric transport is non-uniform about a central axis of the seed crystal. For instance, vapor transport to a left side of the seed crystal may be greater or less than vapor transport to a right side of the seed crystal.

In some examples, the one or more apertures include a first aperture and a second aperture, wherein a width of the first aperture is different from a width of the second aperture. In some examples, the one or more apertures include a first plurality of apertures and a second plurality of apertures, wherein a density of the first plurality of apertures in the baffle is different from a density of the second plurality of apertures in the baffle. In some examples, the first plurality of baffles are in a central portion of the baffle and the second plurality of baffles are in a peripheral portion of the baffle. In some examples, the baffle includes a plurality of dividers arranged in a non-perpendicular direction relative to the growth surface of the seed crystal. In some examples, the one or more apertures are arranged to direct vapor in a direction that is more towards a center of the seed crystal relative to a peripheral portion of the seed crystal. In some examples, the one or more apertures are arranged to direct vapor in a direction that is more towards a peripheral portion of the seed crystal relative to a central portion of the seed crystal.

In some embodiments, one or more apertures may not overlap the seed crystal (e.g., may be aligned outside a peripheral edge of the seed crystal). In some embodiments, one or more apertures may be aligned with an edge of the seed crystal. In some embodiments, one or more apertures may overlap the seed crystal and be aligned within a portion within the edge of the seed crystal. In some embodiments, one or more apertures may overlap a central portion of the seed crystal.

In some examples, the baffle includes a plurality of baffle structures (e.g., baffle plates). In some examples, the baffle includes a first baffle plate having the one or more apertures and a second baffle plate with no apertures. In some examples, the baffle includes a first baffle plate comprising a first aperture and a second baffle plate comprising a second aperture. In some examples, the first aperture is aligned with the second aperture. In some examples, the first aperture is not aligned with the second aperture. In some examples, the first aperture has a different width relative to the second aperture. In some examples, the baffle includes a first baffle plate including a first material and a second baffle plate including a second material. In some examples, the first baffle plate includes graphite and the second baffle plate includes a source material (e.g., secondary source material, silicon carbon source material, carbon source material, etc.). In some examples, the baffle includes a third baffle plate, wherein the third baffle plate includes the first material. In some examples, the second baffle plate is arranged between the first baffle plate and the third baffle plate. In some examples, the first material includes graphite and the second material includes a source material (e.g., silicon carbide source material and/or carbon source material).

In some examples, the baffle includes graphite. In some examples, the baffle includes a coating on the graphite. In some examples, the coating is a pyrolytic coating. In some examples, the coating includes tantalum carbide. Other suitable coatings may be used without deviating from the scope of the present disclosure, such as other carbide coatings, such as vanadium carbide, silicon carbide, etc. Example coatings that may be used are disclosed in U.S. Provisional Application Ser. No. 63/700,682, filed on Sep. 28, 2024, U.S. Provisional Application Ser. No. 63/700,685, filed on Sep. 28, 2024 and U.S. Provisional Application Ser. No. 63/700,686, filed on Sep. 28, 2024, which are incorporated herein by reference.

In some examples, the graphite is porous graphite. For instance, the baffle may have a porosity in a range of about 50% to about 97%, such as about 75% to about 97%, such as about 80% to about 97%. Other suitable materials may be used without deviating from the scope of the present disclosure. For instance, the baffle may comprise a carbide material, such as vanadium carbide, tantalum carbide, silicon carbide. The carbide material may form a bulk of the baffle.

In some examples, at least a portion of the baffle comprises uncoated graphite or exposed graphite. For instance, at least a portion of a surface of the baffle facing the seed crystal may be exposed or uncoated graphite. This will allow that baffle to serve as a secondary source to improve crystal growth during a PVT crystal growth process. The baffle may have undergone various treatments (e.g., may be a treated graphite structure) to reduce carbon inclusions in the baffle. Example treated graphite structures are disclosed in U.S. Provision Application Ser. No. 63/700,630, filed on Sep. 28, 2024 which is incorporated herein by reference.

In some examples, one or more portions of the baffle element, coating, surface or subsurface treatment for the baffle or any of its parts may include an engineered structure having a construction or configuration that is or includes one or more of a porous structure, woven wire, perforated plate, foam, screen printed material, refractory metal, 3D printed structure, coated wire, carbon fiber mesh, carbon wires, refractory metal wires, woven mesh, cast component(s), grid, sintered powder, composite laminate, electroformed structure, braided wire, honeycomb structure, felt structure, nanostructured film, carbon nanotubes, tightly or loosely interconnected network of structures or other suitable construction or configuration. Portions or the entirety of any of the foregoing may be coated, treated and/or converted to form a metal carbide surface, subsurface or entire article of metal carbide. One or more combinations of any of these constructions or configurations may be used without deviating from the scope of the present disclosure. For example, in some embodiments, a first baffle structure (e.g., a first baffle plate) may include a first configuration (e.g., porous material) and a second baffle structure (e.g., a second baffle plate) may include a second configuration (e.g., honeycomb structure).

Aspects of the present disclosure provide technical effects and benefits. For instance, a baffle that physically divides the sublimating source material from the seed crystal provides more control over radiative heat transfer between the sublimating source material and the seed. In general, modifications to the temperature of the seed crystal modifies the surface free energy of the seed crystal. The surface free energy plays a large role in the formation of the crystal lattice, defect sites, growth rate, etc. By providing more control over a thermal gradient between the source material and the seed crystal, a level of control over surface energy of the seed may be achieved, which could result in a reduction of stresses in the crystal grown from the seed.

Further, a baffle that modifies the advective and convective transport of source vapor to the seed may provide control over the direction that vapor arrives at the seed, which may enhance deposition processes at the growth front of the seed crystal. Additionally, altering the path that vapor travels (e.g., shortening or elongating) or other factors (e.g., vapor velocity) alters the driving forces of diffusion, providing more control over growth parameters.

In addition, if a large surface area of material that is non-reactive or inert with respect to carbon and silicon species is provided, the inert material may provide a catalytic surface that facilitates gas-gas reactions (e.g., to change ratios of silicon, carbon, and/or species containing silicon and/or carbon in the vapor). That is, gas stoichiometry in the vicinity of the baffle may be brought towards equilibrium. This may facilitate enhanced growth rates and less material waste. In some embodiments, at least a portion of the baffle may have a chemically active surface or coating that may be used to reduce contaminates, impurities, and inclusions in vapor transported through the baffle.

Further, if a large surface area of material that is non-reactive or inert with respect to carbon and silicon species is provided, the inert material may provide a surface on which undesired contaminants may be adsorbed. In some instances, undesired species may be introduced to the reaction crucible that could damage reactor components, contaminate the source material, or be introduced to the seed crystal and form defects. A baffle may filter the undesired species through adsorption. Further, filtration of larger particles, such as carbon-based particulates released from reactor components, may be possible. As such, including a baffle in a crystal growth system provides multiple avenues to reduce defect formation within a crystal grown from a seed in a PVT process, in addition to benefits of defect agglomeration as a result of the geometry of the baffle.

In addition, the baffle may potentially act as a second source (e.g., a carbon source). For instance, if a reactive material is used as a baffle (e.g., uncoated or exposed graphite), the baffle may be etched such that the baffle contributes positively to species interacting with the seed crystal during a growth process. The baffle can be made of a reactive material that captures parasitic silicon carbide, or silicon carbide that crystallizes in an undesirable location, and act as a dynamic source if the captured silicon carbide is sublimated, if desired. Further, the baffle may act as an additional gas injection site for process gases.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “central portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel. “Non-perpendicular” means not perpendicular.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

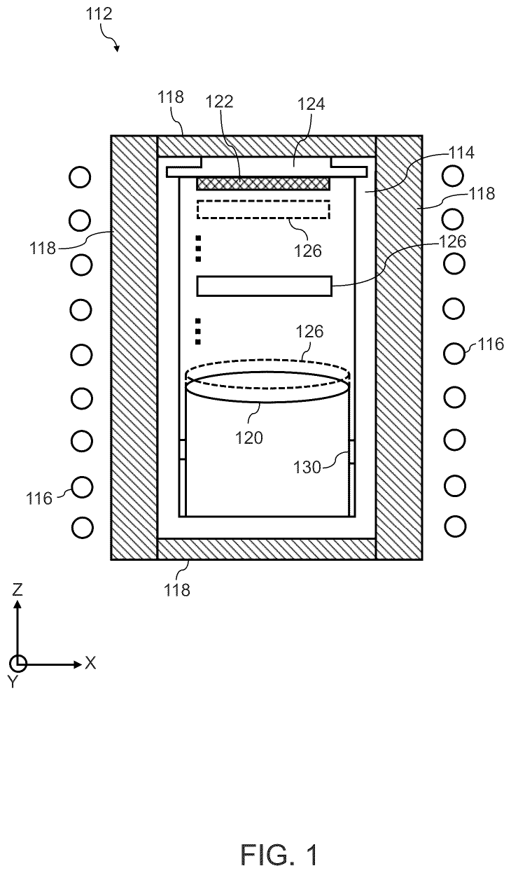

FIG. 1 is a cross-sectional schematic diagram of a crystal growth system 112 adapted for use in a crystal growth process of the type contemplated by certain embodiments of the disclosure. The crystal growth system 112 includes a reaction crucible 114 (also referred to as a susceptor or growth cell) and a plurality of induction coils 116 adapted to heat the reaction crucible 114 when electrical current is applied. Alternatively, a resistive heating approach may be applied to the heating of the reaction crucible 114. Using any competent heating mechanism and approach, the temperature within the crystal growth system 112 may be controllable. The reaction crucible 114 may be, at least in part, a graphite structure.

The crystal growth system 112 may also include one or more gas inlet and gas outlet ports and associated equipment allowing the controlled introduction and evacuation of gas from an environment surrounding the reaction crucible 114. The introduction and evacuation of various gasses to or from the environment surrounding the reaction crucible 114 may be accomplished using a variety of inlets/outlets, pipes, valves, pumps, gas sources, and controllers. It will be further understood by those skilled in the art, using the disclosures provided herein, that the crystal growth system 112 may further incorporate in certain embodiments a water-cooled quartz vessel.

The reaction crucible 114 may be surrounded by an insulation material 118. The composition, size, and placement of the insulation material 118 will vary with an individual crystal growth system, such as the crystal growth system 112 of FIG. 1, to define and/or maintain desired thermal gradients (both axially and radially) in relation to the reaction crucible 114. For purposes of clarity, the term, “thermal gradient,” will be used herein to describe one or more thermal gradient(s) associated with or within the reaction crucible 114. Those skilled in the art, using the disclosures provided herein, recognize that “the thermal gradient” established in embodiments of the disclosure will contain (or may be further characterized as having) axial and radial gradients, or may be characterized by a plurality of isotherms.

Prior to establishment of the thermal gradient, the reaction crucible 114 is loaded with a source material 120 (e.g., silicon carbide vapor source material, such as a silicon carbide powder or solid silicon carbide source). Example silicon carbide source materials are disclosed in U.S. Provisional Application Ser. No. 63/689,294, filed on Aug. 30, 2024 and in U.S. Provisional Application Ser. No. 63/689,291, filed on Aug. 30, 2024, both of which are incorporated herein by reference. As such, the reaction crucible 114 includes one or more portions, at least one of which is capable of providing the source material 120. The source material 120 may be held in a lower portion of the reaction crucible 114, as is common for one type of crystal growth system, such as the crystal growth system 112 of FIG. 1.

A seed crystal 122 may be placed above or in an upper portion of the reaction crucible 114. The seed crystal 122 may take the form of a silicon carbide seed wafer having a diameter, for instance, from about 50 mm to about 310 mm or greater. A silicon carbide crystal boule will be grown from the seed crystal 122 during a crystal growth process.

In the embodiment illustrated in FIG. 1, a seed holder 124 is used to hold the seed crystal 122. The seed holder 124 is securely attached to the reaction crucible 114 in an appropriate fashion. For example, in the orientation illustrated in FIG. 1, the seed holder 124 is attached to an uppermost portion of the reaction crucible 114 to hold the seed crystal 122 in a desired position. In some embodiments, the seed holder 124 is fabricated from carbon (e.g., graphite). The attachment of the seed crystal 122 (e.g., a seed wafer) to the seed holder 124 within the crystal growth system 112 may be made, for instance, by a uniform thermal contact. Various techniques may be used to implement a uniform thermal contact. For example, the seed crystal 122 may be placed in direct physical contact with the seed holder 124, or an adhesive may be used to fix the seed crystal 122 to the seed holder 124, so as to provide uniform conductive and/or radiative heat transfer over substantially the entire area between the seed crystal 122 and the seed holder 124.

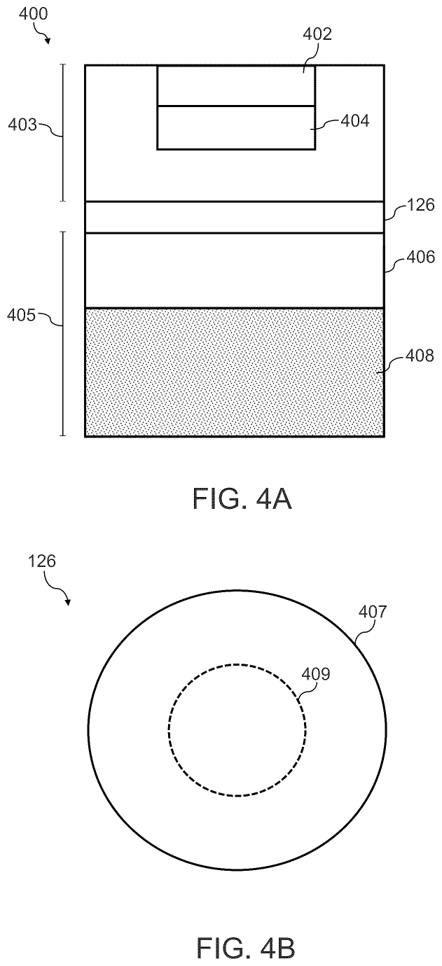

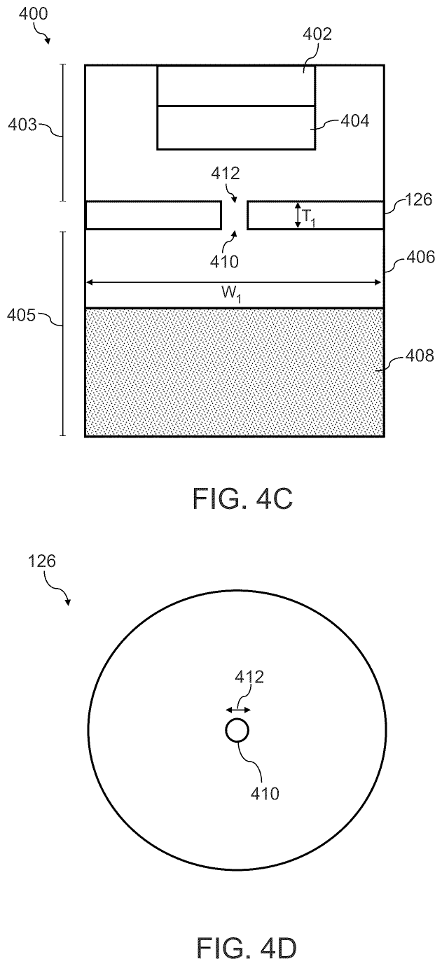

According to example aspects of the present disclosure, the crystal growth system 112 may include a baffle 126 that may be situated on the source material 120 or at any other location within the crystal growth system 112, such as between the source material 120 and the seed crystal 122 as illustrated in FIG. 1. The baffle 126 may provide a mechanism for transport of source vapor or other process gas during sublimation of the source material 120. The baffle 126 may filter or otherwise reduce impurities from the source material 120 that may inadvertently sublimate in a crystal growth process. The baffle 126 may provide for control radiative heat transfer. The baffle 126 may have any spatial orientation relative to the source material 120, the seed crystal 122, and/or the reaction crucible 114. The baffle 126 may include any of the baffles discussed in relation to FIGS. 4A-44.

As shown in FIG. 1, the baffle 126 or baffle elements may be located on the source material, may be spaced apart from the source material 120 and/or the seed material 122, or may be proximate the seed material 122. In some embodiments, the system 112 may include any number of baffles or baffle elements without deviating from the scope of the present disclosure. In some embodiments, the source material 120 may have a baffle 126 or baffle element incorporated therein.

Further, the crystal growth system 112 may optionally include the source material holder 130. The source material holder 130 may be, for example, one or more graphite components within the reaction crucible 114 that brace, support, or hold the source material 120. In some embodiments, the source material holder 130 may be attached to the inner walls of the reaction crucible 114, as shown in FIG. 1.

FIG. 1 depicts a coordinate system having an x-axis as a horizontal axis, a y-axis that is in and out of the page, and a z-axis that is a vertical axis. A width dimension refers to a dimension along the x-axis or y-axis. A thickness dimension refers to a dimension along the z-axis. For the sake of clarity, any dimension along the x-axis or y-axis may be considered a width dimension regardless of whether it is the shortest or longest dimension in a plane defined by the x-axis and y-axis.

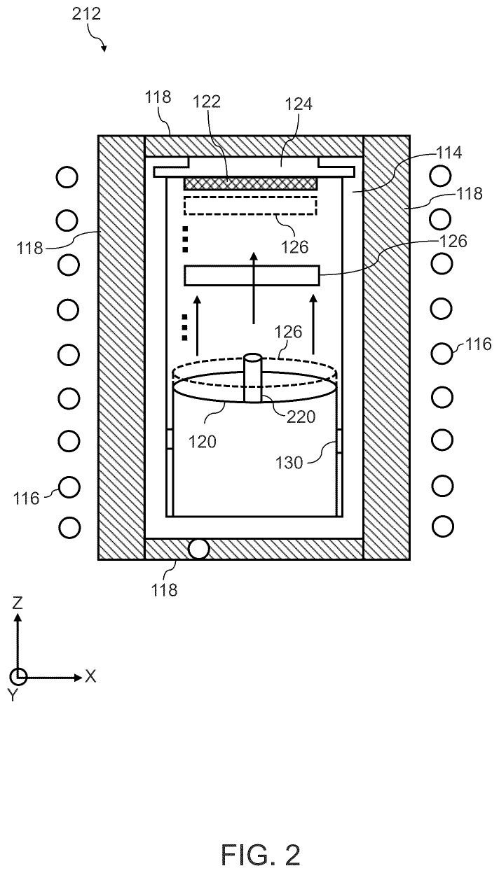

In one example embodiment, shown in FIG. 2, the crystal growth system 132 may be similar to that shown in FIG. 1, but may also include an inlet 134 for introducing a dopant (e.g., N2) to the reaction crucible 114. The inlet 134, may be, for example, a tube, pipe, vent, or the like. In some embodiments, the source material 120 may surround the inlet 134. For example, in some embodiments, the source material 120 may include a channel through which the inlet 134 is provided. In other embodiments, the source material 120 may include a plurality of subcomponents (attached or detached) which surround the inlet 134. The inlet 134 may be connected to a dopant-containing gas source (not shown) and configured to introduce the dopant-containing gas to the reaction crucible 114. An example of a dopant-containing gas is nitrogen.

The crystal growth system 132 may include the baffle 126 that may be situated within the reaction crucible 114. The baffle 126 may provide a mechanism for the transport of source vapor during sublimation of the source material 120. The baffle 126 may have any spatial orientation relative to the source material 120, the seed crystal 122, and/or the reaction crucible 114. The baffle 126 may filter or otherwise reduce impurities from the source material 120 that may inadvertently sublimate in a crystal growth process. The baffle 126 may provide for control of radiative heat transfer. The baffle 126 may include any of the baffles discussed in relation to FIGS. 4A-44.

As shown in FIG. 2, the baffle 126 or baffle elements may be located on the source material, may be spaced apart from the source material 120 and/or the seed material 122, or may be proximate the seed material 122. In some embodiments, the system 212 may include any number of baffles or baffle elements without deviating from the scope of the present disclosure. In some embodiments, the source material 120 may have a baffle 126 or baffle element incorporated therein.

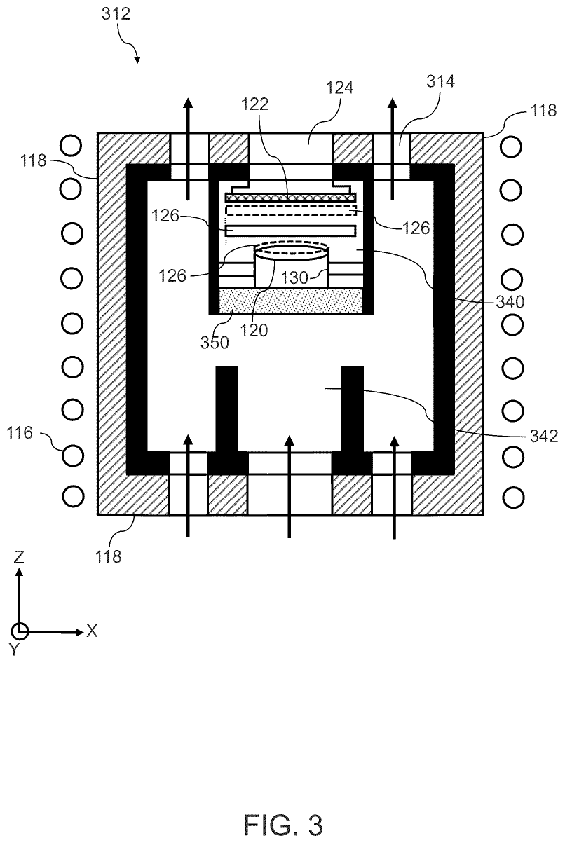

In another example embodiment, shown in FIG. 3, the crystal growth system 142 may be a continuous feed PVT (CF-PVT) system. In a CF-PVT system, such as the crystal growth system 142 of FIG. 3, the reaction crucible may include an upper chamber 144 and a lower chamber 146. The upper chamber 144 may include the source material 120 and the seed crystal 122. The upper chamber 144 may be separated from the lower chamber 146 by a foamed structure 150. The foamed structure 150 may be formed, for example, from a gas-permeable graphite foam. The source material 120 may be placed on the foamed structure 150 within the upper chamber 144. A gaseous silicon source (e.g., trimethylsilane diluted in argon) may be supplied to the lower chamber 146. As the gaseous silicon source is transported through the foamed structure 150, it may react with a carbon source within the foamed structure 150 (e.g., graphite) to form silicon carbide. A CF-PVT system, such as the crystal growth system 142 of FIG. 3, combines a PVT process for the growth of single crystals and high temperature chemical vapor deposition (HTCVD) processes for the in-situ formation and continuous feeding of a high purity polycrystalline source. A CF-PVT system, such as the crystal growth system 142 of FIG. 3, may be particularly useful for growing 3C silicon carbide.

The crystal growth system 142 may include a baffle 126 that may be situated within the upper chamber 144 of the reaction crucible. The baffle 126 may provide a mechanism for the transport of source vapor during sublimation of the source material 120. The baffle 126 may filter or otherwise reduce impurities from the source material 120 that may inadvertently sublimate in a crystal growth process. The baffle 126 may provide for control over radiative heat transfer. The baffle 126 may have any spatial orientation relative to the source material 120, the seed crystal 122, and/or the upper chamber 144 of the reaction crucible. The baffle 126 may include any of the baffles discussed in relation to FIGS. 4A-43B.

As shown in FIG. 3, the baffle 126 or baffle elements may be located on the source material, may be spaced apart from the source material 120 and/or the seed material 122, or may be proximate the seed material 122. In some embodiments, the system 312 may include any number of baffles or baffle elements without deviating from the scope of the present disclosure. In some embodiments, the source material 120 may have a baffle 126 or baffle element incorporated therein.

In any of the embodiments shown in FIGS. 1-3, the crystal growth systems 112, 212, 312, and/or the reaction crucible 114 may be implemented in a number of different geometries, or any suitable configurations, and may hold the source material 120 accordingly. Thus, while embodiments of the present disclosure may be illustrated with certain designs of the reaction crucible 114, the scope of the present disclosure is not limited to such designs but will find application in different crystal growth system designs using many different types of reaction crucibles. In some examples, the crystal growth processes (e.g., the processes conducting in any of the embodiments shown in FIGS. 1-3) may be conducted at process temperatures in a range of 1700° C. to about 2600° C.

For any of the crystal growth systems provided herein, one or more parts of the crystal growth system or the source material may be 3D printed, such as disclosed in U.S. Provisional Application Ser. No. 63/689,298, which is incorporated herein by reference.

In any of the simplified crystal growth systems with a baffle 126 depicted in FIGS. 4A-44C, the baffle 126 may provide vapor transport of a silicon carbide source vapor through a first portion of the baffle 126 at a first rate. In some embodiments, the silicon carbide vapor may be transported through a second portion of the baffle 126 (e.g., including one or more apertures), at a second rate. The first rate may be different than the second rate. For example, the baffle 126 may provide an avenue for source vapor to transport through the material of the baffle 126 at a first rate, while source vapor is transported through an aperture unimpeded by the material of the baffle 126 at a second rate. In embodiments including one or more apertures, a maximum width of the aperture may be less than about 2 mm to about 10 mm, such as 3 mm to about 8 mm, such as about 4 mm to about 6 mm. In some embodiments, the baffle 126 may be spaced apart from the seed holder 402 and is not coupled to the seed holder 402. In some embodiments, the baffle 126 may impede or otherwise alter radiative heat transfer or thermal energy within the crystal growth chamber in a crystal growth process. This may provide more control over a thermal gradient or thermodynamic and kinetic factors of diffusion and deposition processes that are influential in a crystal growth process. For instance, the sublimation rate of the source material 408 is directly proportional to the temperature of the source material 408. As such, shielding the seed crystal 404 from excessive thermal radiation required to sublimate the source material 408 may allow a higher sublimation rate to be utilized.

In some embodiments, the baffle 126 may be, at least partially, made of graphite. In some embodiments, the baffle 126 made at least partially of graphite may include a coating on at least a portion of the graphite. In some embodiments, the coating on the baffle 126 made of graphite may be a pyrolytic coating. In some embodiments, the coating on the baffle 126 made of graphite may be tantalum carbide. Other suitable coatings may be used without deviating from the scope of the present disclosure, such as other carbide coatings, such as vanadium carbide, silicon carbide, etc. In some embodiments, the coating on the baffle 126 may hinder particulate matter larger than the source vapor from reaching a seed crystal 404. In some embodiments, the baffle 126 may be porous graphite. Porous graphite may provide a less hindered pathway for source vapor to diffuse through.

In some examples, the graphite is porous graphite. For instance, the baffle 126 may have a porosity in a range of about 50% to about 97%, such as about 75% to about 97%, such as about 80% to about 97%. Other suitable materials may be used without deviating from the scope of the present disclosure. For instance, the baffle 126 may comprise a carbide material, such as vanadium carbide, tantalum carbide, silicon carbide. The carbide material may form a bulk of the baffle 126.

In some examples, at least a portion of the baffle 126 includes uncoated graphite or exposed graphite. For instance, at least a portion of a surface of the baffle 126 facing the seed crystal 404 may be exposed or uncoated graphite. This will allow that baffle 126 to serve as a secondary source to improve crystal growth during a PVT crystal growth process. The baffle 126 may have undergone various treatments (e.g., may be a treated graphite structure) to reduce carbon inclusions in the baffle 126. Example treated graphite structures are disclosed in U.S. Provision Application Ser. No. 63/700,630, filed on Sep. 28, 2024 which is incorporated herein by reference.

The seed crystal 404 may be a silicon carbide seed crystal. In some embodiments, the baffle 126 may be spaced apart from a seed holder 402 and is not coupled to the seed holder 402. In some embodiments, the baffle 126 may be spaced apart from a source material 408 and is not coupled to the source material 408. The source material 408 may be a silicon carbide vapor source material. In some embodiments, the baffle may be coupled to a side wall of a crucible 406. In some embodiments, the baffle 126, or an individual baffle plate in embodiments including a plurality of baffle plates or baffle structures, may have a thickness that is in a range of about 0.5 mm to about 25 mm, such as 2 mm to about 12 mm, such as about 2 mm to about 8 mm.

In some embodiments, the baffle 126 can include single or multiple elements that perform one of more of the following: effecting/providing temperature gradient in a desired manner relative to the crystal growth surface, effecting/providing vapor pressure/flux/flow for/to/from the source material (e.g., silicon carbon source material, secondary source material, or dopant source relative to the crystal growth surface, side surface of the seed crystal and/or areas within the reactor susceptible to parasitic growth; and filtering graphite or other inclusions from the crystal. In some embodiments, different elements or portions of the baffle 126 can provide different features, such as one element for filtering, another element acting as a secondary source (e.g., a graphite element that provides a carbon source and provides temperature gradient and vapor pressure/flux effects); and an element with apertures, pores, voids, cavities, indentations and/or protrusions to effect temperature gradient and/or vapor flow/pressure effects. One or more of the baffles 126 can be coated with a high temperature carbide, such as TaC or the like) while others are not. Portions or the entire baffle can be coated or not with a single, multiple and/or patterned coating(s), for instance, to achieve desired sublimation if acting as a secondary source, or to reduce sublimation if not intended to serve as a secondary source. Individual baffles or baffle elements can serve duplicate or different functions.

FIG. 4A depicts a crystal growth system 400 according to example embodiments of the present disclosure. The crystal growth system 400 includes the seed holder 402 configured to hold the seed crystal 404. The seed crystal 404 may provide a growth surface for growth of the silicon carbide crystalline material in a crystal growth process. The crystal growth system 400 includes the crucible 406 defining a crystal growth chamber. The crystal growth system 400 includes the source material 408. The crystal growth system 400 includes the baffle 126 within the crystal growth chamber that is spaced apart from the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

The baffle 126 may be a porous baffle 126. For instance, the baffle 126 may have a porosity of greater than about 70% by volume, such as greater than about 80% by volume. In some embodiments, the baffle 126 has a porosity in a range of about 70% to about 97%, such as about 80% to about 97%, such as about 85% to about 97%.

As shown in FIG. 4B, in some embodiments, the baffle 126 may have a first portion 407 and a second portion 409. The first portion 407 may have a first porosity and the second portion 409 may have a second porosity. The first porosity may be different than the second porosity. For instance, the first porosity may be greater than about 70%. The second porosity may be less than about 70%, such as less than about 50%. The baffle 126 of FIG. 4B may be a monolithic structure or may include attached sub-components.

The embodiment of FIG. 4B depicts one example division of the baffle 126 into a first portion 407 and a second portion 409 for purposes of illustration and discussion. In the example of FIG. 4B, the first portion 407 may at least partially overlap a peripheral portion of the seed crystal 404 and the second portion 409 may overlap a central portion of the seed crystal 404. The baffle 126 of FIG. 4B may provide non-uniform vapor transport. In some embodiments, the non-uniform vapor transport may be asymmetric about a central axis of the seed crystal (e.g., vapor transport to a left side of the seed crystal 404 is greater than vapor transport to a right side of the seed crystal 404).

Other suitable divisions of the baffle 126 into portions with different porosities are within the scope of the present disclosure. For instance, in some embodiments, the non-uniform vapor transport may be asymmetric about a central axis of the seed crystal (e.g., vapor transport to a left side of the seed crystal 404 is greater than vapor transport to a right side of the seed crystal 404).

FIG. 4C depicts a crystal growth system 400 according to example aspects of the present disclosure. The crystal growth system 400 includes the seed holder 402 configured to hold the seed crystal 404. The seed crystal 404 may provide a growth surface for growth of the silicon carbide crystalline material in a crystal growth process. The crystal growth system 400 includes the crucible 406 defining a crystal growth chamber. The crystal growth system 400 includes the source material 408. The crystal growth system 400 includes the baffle 126 within the crystal growth chamber that is spaced apart from the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

The baffle 126 has a long dimension (e.g., width) WI and a thickness T1. The thickness T1 is in a general direction of vapor transport through the baffle 126. In some embodiments, the long dimension WI is in a direction that is non-perpendicular to the growth surface of the seed crystal 404. In some embodiments, the long dimension WI is at least 5 times greater than the thickness T1, such as at least 10 times greater, such as at least 20 times greater, such as at least 50 times greater, such as in a range of about 5 times greater to about 50 times greater, such as in a range of about 10 times greater to about 50 times greater, such as in a range of about 10 times greater to about 20 times greater.

As depicted in the top view of the baffle 126 in FIG. 4D, the baffle 126 includes an aperture 410 defined through a thickness of the baffle 126. The aperture 410 may be positioned such that the aperture 410 may provide a pathway for the transport of source vapor unimpeded by the material of the baffle 126 to travel primarily to a central portion of the seed crystal 404. The aperture 410 is depicted as being a narrow aperture. The aperture may have any suitable width (e.g., diameter) such that the aperture 410 has a width 412 that is 20% or less than a width of the crystal growth chamber, such as about 15% or less, such as about 10% or less, such as about 5% or less such as about 0.5 mm to about 10 mm, such as about 3 mm to about 8 mm, such as 4 mm to about 6 mm. The aperture 410 may provide a direct path (e.g., a path between the upper portion 403 and the lower portion 405 of the crystal growth chamber that is linear or otherwise unobstructed) through the baffle 126 for transport of vapor from the silicon carbide vapor source material 408 to the seed crystal 404 without having significant crystal growth formation in the aperture 410. The aperture 410 is depicted as being a generally circular aperture, it will be understood that the aperture 410 may include any suitable shape or configuration, such as a generally square shape, a generally rectangular shape, a generally triangular shape, etc.

The aperture 410 overlaps a central portion of the seed crystal 404. In some examples, the aperture 410 may not overlap the seed crystal 404, or may be aligned with an edge of the seed crystal 404, or may be aligned with a portion within the edges of the seed crystal 404 without deviating from the scope of the present disclosure. The aperture 410 is depicted as a circular hole. In any of the embodiments provided herein, the one or more apertures may include one or more holes, rings, or other shaped apertures.

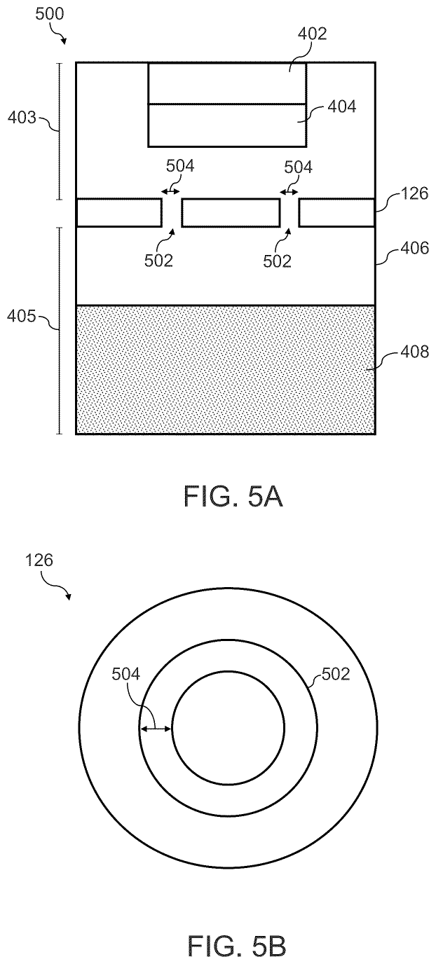

For instance, FIG. 5A depicts a crystal growth system 500 according to example embodiments of the present disclosure. Similar to the crystal growth system of FIGS. 4A-4D, the crystal growth system 500 includes the baffle 126, the seed holder 402, the seed crystal 404, the crucible 406, and the source material 408. In some embodiments, the baffle 126 may extend between the inner walls of the crucible 406, such that the crucible 406 is bisected or divided into the upper portion 403 and the lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the top view of the baffle 126 in FIG. 5B, the aperture comprises an annular aperture 502 defined through a thickness of the baffle 126. The annular aperture 502 may provide a direct path (e.g., a path between the upper portion 403 and the lower portion 405 of the crystal growth chamber that is linear or otherwise unobstructed) in a ring-like structure, such that source vapor is transported unimpeded by the material of the baffle 126 to a peripheral portion of the seed crystal 404. The annular aperture 502 is depicted as being a narrow aperture with a width 504. The aperture may have any suitable width such that the annular aperture 510 has the width 504 that is 20% or less of a width of the crystal growth chamber, such as about 15% or less, such as about 10% or less, such as about 5% or less, such as about 0.5 mm to about 10 mm, such as 3 mm to about 8 mm, such as 4 mm to about 6 mm. The annular aperture 502 may provide a path through the baffle 126 for transport of vapor from the source material 408 to the seed crystal 404 without having significant crystal growth formation in the annular aperture 502.

The annular aperture 502 of FIGS. 5A and 5B is depicted as overlapping the peripheral portion of the seed crystal 404 for purposes of illustration and discussion. In some embodiments, the annular aperture 502 may overlap a central portion of the seed crystal 404. In some embodiments, the annular aperture 502 may not overlap the seed crystal 404 and may be provided to provide increased vapor transport along the sidewall of the seed crystal 404. The annular aperture 502 may include one or more support structures (not illustrated) that extend across the aperture 502. The one or more support structure(s) may include any suitable structure or configuration required to mechanically support portions of the baffle 126.

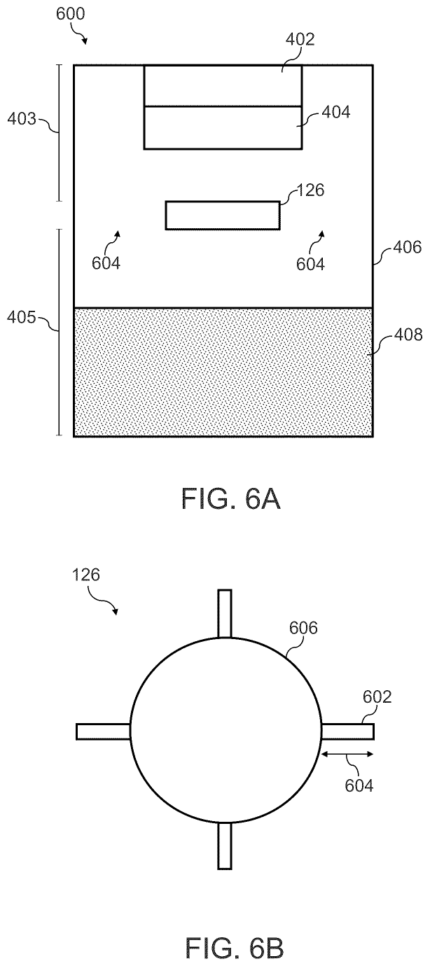

Like the crystal growth systems of FIGS. 4A and 5A, the crystal growth system 600 of FIG. 6A includes many similar components. The crystal growth system 600 includes the baffle 126, the seed holder 402, the seed crystal 404, the crucible 406, and the source material 408. In some embodiments, the baffle 126 may extend between the inner walls of the crucible 406, such that the crucible 406 is bisected or divided into the upper portion 403 and the lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the top view of the baffle 126 in FIG. 6B, the baffle 126 may include one or more support structure(s) 602 that may have a width 604. The support structures may be configured such that a central portion 606 of the baffle 126 with no apertures overlaps a central portion of the seed crystal 404. The source vapor may be transported linearly or otherwise unobstructed by the baffle 126, through a gap formed between the central portion 606 of the baffle and the crucible 406 or other structure of the crystal growth system 600. FIG. 6A depicts the baffle 126 having the central portion 606 with no apertures as overlapping a central portion of the seed crystal 404 for purposes of illustration and discussion. In some embodiments, the portion of the baffle 126 with no apertures may overlap a peripheral portion of the seed crystal 404. In some embodiments, the central portion 606 of the baffle 126 may overlap the peripheral portion and the central portion of the seed crystal 404 to provide increased vapor transport along the sidewall of the seed crystal 404.

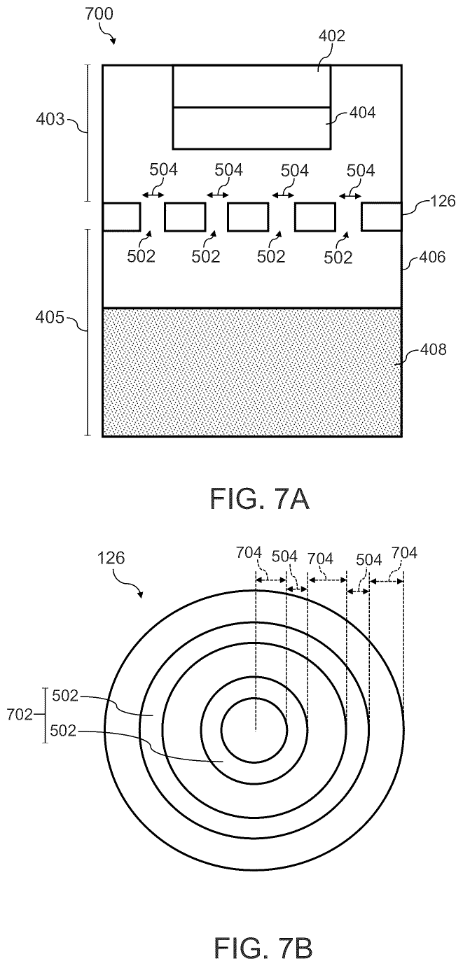

Like the crystal growth systems of FIGS. 4A-6A, the crystal growth system 700 of FIG. 7A includes many similar components. The crystal growth system 700 includes the baffle 126, the seed holder 402, the seed crystal 404, the crucible 406, and the source material 408. In some embodiments, the baffle 126 may extend between the inner walls of the crucible 406, such that the crucible 406 is bisected or divided into an upper region and a lower region by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the top view of the baffle 126 in FIG. 7B, the baffle 126 may include a plurality of annular apertures 702 (e.g., including one or more of the annular apertures 502) defined through a thickness of the baffle 126. The plurality of annular apertures 702 may provide a direct path (e.g., a path between the upper portion 403 and the lower portion 405 of the crystal growth chamber that is linear or otherwise unobstructed) in a ring-like structure. That is, the source vapor may be transported unimpeded by the material of the baffle 126 to the peripheral portion of the seed crystal 404 and the sidewall of the seed crystal 404. The annular apertures 502 that the plurality of apertures 702 includes are depicted as being narrow apertures with the width 504. The annular aperture(s) 502 may have any suitable width such that the annular aperture 502 has the width 504 that is about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. The plurality of annular apertures 702 may provide a path through the baffle 126 for transport of vapor from the source material 408 to the seed crystal 404 without having significant crystal growth formation in the plurality of annular apertures 702.

In the example depicted in FIG. 7B, the plurality of annular apertures 702 may have the width 504 that is consistent (e.g., largely the same dimension) across the plurality of annular apertures 702. Each annular aperture 502 in the plurality of annular apertures 702 may be equidistant (e.g., symmetrical) and include a consistent spacing 704 between each annular aperture 502. The geometry (e.g., the width) of the spacing 704 between each of the annular apertures 502 is for purposes of discussion only and is not meant to represent a physical scale of the spacing 704. The spacing 704 may have any dimension (e.g., width) to create the baffle 126 with the plurality of annular apertures 702 with the spacing 704 that is a consistent dimension (e.g., width). Further, the plurality of annular apertures 702 is depicted as including two annular apertures 502 for the purposes of discussion only, the plurality of annular apertures 702 may include any number of the annular apertures 502, such as two or more annular apertures 502, three or more annular apertures, or four or more annular apertures. The plurality of annular apertures 702 may provide a path through the baffle 126 for transport of vapor from the source material 408 to the seed crystal 404 without having significant crystal growth formation in the plurality of annular apertures 702. The annular apertures 502 may include one or more of support structure (not pictured) that extend across the apertures 502. The one or more support structure(s) may include any suitable structure or configuration required to mechanically support portions of the baffle 126.

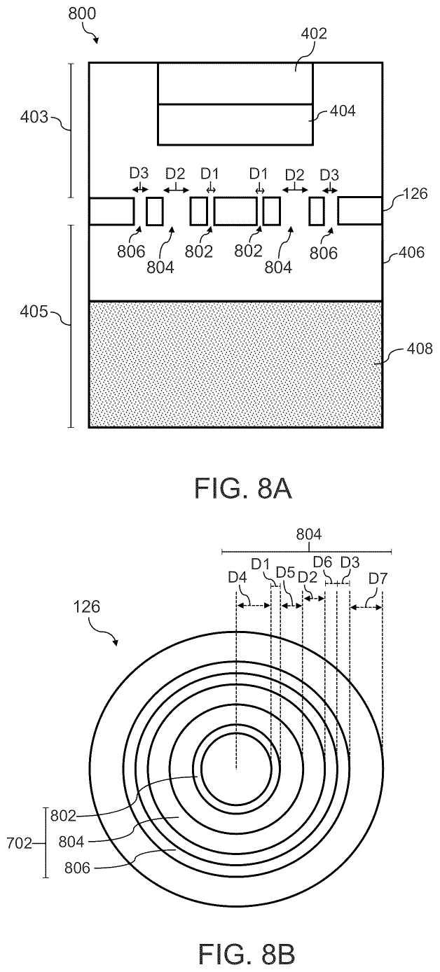

Like the crystal growth systems of FIGS. 4A-7A, the crystal growth system 800 of FIG. 8A includes many similar components. The crystal growth system 800 includes the baffle 126, the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the top view of the baffle 126 in FIG. 8B, the baffle 126 may include the plurality of annular apertures 702 (e.g., including one or more of the annular apertures 802, 804, 806) defined through of a thickness the baffle 126. The plurality of annular apertures 702 may provide a direct path (e.g., a path between the upper portion 403 and the lower portion 405 of the crystal growth chamber that is linear or otherwise unobstructed) in a ring-like structure. That is, the source vapor may be transported unimpeded by the material of the baffle 126 to a sidewall of the seed crystal 404, as in the annular aperture 806, to the peripheral portion of the seed crystal 404, as in the annular aperture 804, and to a region closer to the central portion of the seed crystal 404, as in the annular aperture 802. The plurality of annular apertures 702 may have a plurality of thicknesses that are not consistent (e.g., not the same dimension, width) across the plurality of annular apertures 702. For instance, the annular aperture 802 may have a width D1. The annular aperture 804 may have a width D2. The annular aperture 806 may have a width D3. The widths D1, D2, and D3 may be the same, or may differ from one another. The thicknesses D1, D2, and D3 of each of the annular apertures 802, 804, 806 may be such that the widths D1, D2, D3 are about 0% or less than a width of the crystal growth chamber, such as about 15% or less, such as about 10% or less, such as about 5% or less.

Each of the annular apertures 802, 804, 806 in the plurality of annular apertures 702 may be equidistant from the center of the baffle 126 (e.g., symmetrical). The spacing between each of the annular apertures 802, 804, 806 may differ. For instance, the annular aperture 802 may have a spacing D4 from a central portion of the baffle 126. The annular aperture 804 may have a spacing D5 from the annular aperture 802. The annular aperture 806 may have a spacing D6 from the annular aperture 804, or a spacing D7 from the crucible 406. The spacing D4, D5, D6, and D7 may be the same, or may differ. The spacing D4, D5, D6, and/or D7 are illustrated for purposes of discussion only and are not meant to represent the spacing D4, D5, D6 and/or D7 to scale, the spacing D4, D5, D6, and/or D7 may have any dimension (e.g., width) as required to create the plurality of annular apertures 702. Further, the plurality of annular apertures 702 is depicted as including three of the annular apertures 802, 804, 806 for the purposes of discussion only, the plurality of annular apertures 702 may include any number of the annular apertures. The plurality of annular apertures 702 may provide a path through the baffle 126 for transport of vapor from the source material 408 to the seed crystal 404 without having significant crystal growth formation in the plurality of annular apertures 702. The annular apertures may include one or more of support structure (not illustrated) that extend across the apertures 802, 804, 806. The one or more support structure(s) may include any suitable structure or configuration required to mechanically support portions of the baffle 126.

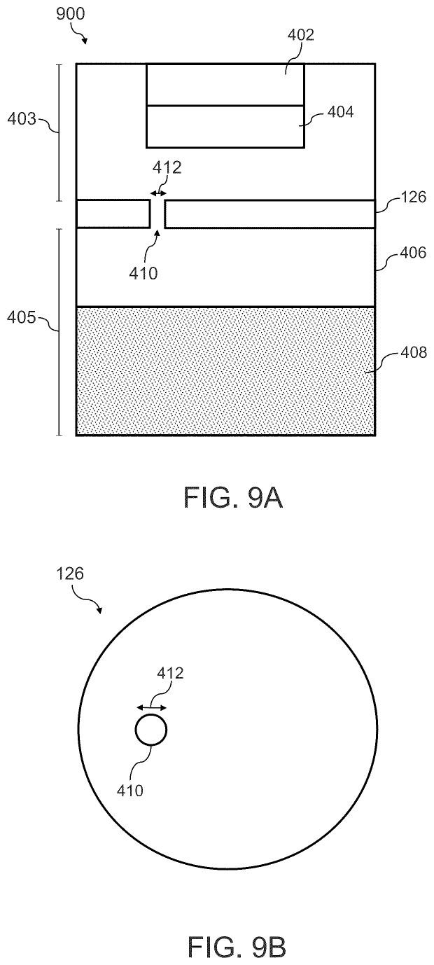

Like the crystal growth systems of FIGS. 4A-8A, the crystal growth system 900 of FIG. 9A includes many similar components. The crystal growth system 900 includes the baffle 126, the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the top view of the baffle 126 in FIG. 9B, the baffle 126 includes the aperture 410 defined through of a thickness of the baffle 126. The aperture 410 is depicted as being a generally circular aperture, it will be understood that the aperture may include any suitable shape or configuration, such as a generally square shape, a generally rectangular shape, a generally triangular shape, etc. The aperture 410 may be positioned such that the aperture 410 may provide a linear pathway for the transport of source vapor unimpeded by the material of the baffle 126 to travel asymmetrically to one side of a peripheral portion of the seed crystal 404. The aperture 410 is depicted as being a narrow aperture with the width 412. The aperture may have any suitable width (e.g., diameter) such that the aperture 410 has the width 412 that is about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. The aperture 410 may provide a direct path (e.g., a path between the upper portion 403 and the lower portion 405 of the crystal growth chamber that is linear or otherwise unobstructed) through the baffle 126 for transport of vapor from the silicon carbide vapor source material 408 to the seed crystal 404 without having significant crystal growth formation in the aperture 410. The aperture 410 may provide asymmetric vapor transport to the seed crystal 404.

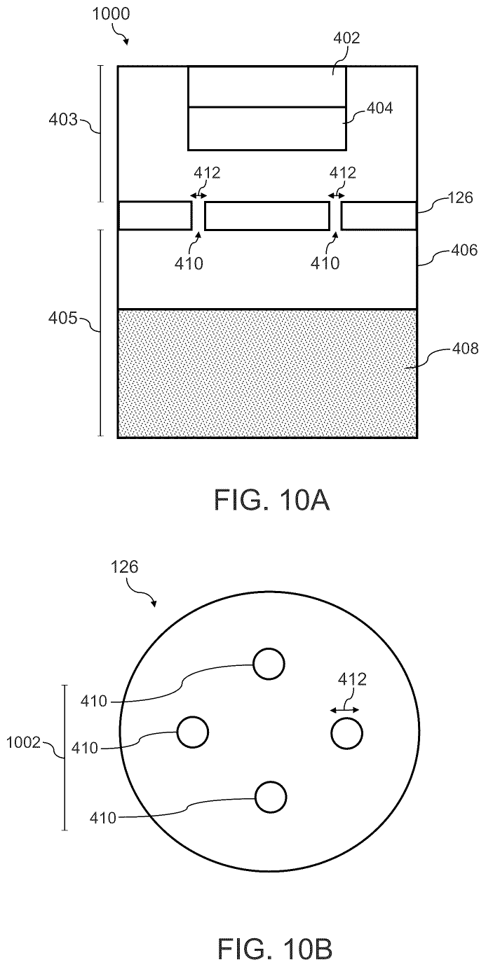

Like the crystal growth systems of FIGS. 4A-9A, the crystal growth system 1000 of FIG. 10A includes many similar components. The crystal growth system 1000 includes the baffle 126, the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the top view of the baffle 126 in FIG. 10B, the baffle 126 includes a plurality of apertures 1002 (e.g., including two or more of the aperture 410) defined through a thickness of the baffle 126. The apertures 410 in the plurality of apertures 1002 are depicted as being generally circular apertures, it will be understood that the aperture 410 may include any suitable shape or configuration, such as a generally square shape, a generally rectangular shape, a generally triangular shape, etc. The plurality of apertures 1002 may be positioned such that the plurality of apertures 1002 may provide a linear pathway for the transport of source vapor unimpeded by the material of the baffle 126 to travel to peripheral portions of the seed crystal 404. The apertures 410 of the plurality of apertures 1002 are depicted as having a small width 412 that is a similar width. The apertures 410 may have any suitable width (e.g., diameter) such that the apertures 410 have the width 412 that is about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. The plurality of apertures 1002 may provide a direct path (e.g., a path between the upper portion 403 and the lower portion 405 of the crystal growth chamber that is linear or otherwise unobstructed) through the baffle 126 for transport of vapor from the source material 408 to the seed crystal 404 without having significant crystal growth formation in the plurality of apertures 1002. The plurality of apertures 1002 may be arranged in any suitable pattern without deviating from the scope of the present disclosure.

In some embodiments, one or more of the plurality of apertures 1002 may include rings or other shaped apertures. One or more of the plurality of apertures 1002 may not overlap the seed crystal 404, may be aligned with an edge of the seed crystal 404, may be aligned with a portion of the seed crystal within the edges of the seed crystal 404, and/or may overlap a central portion of the seed crystal 404.

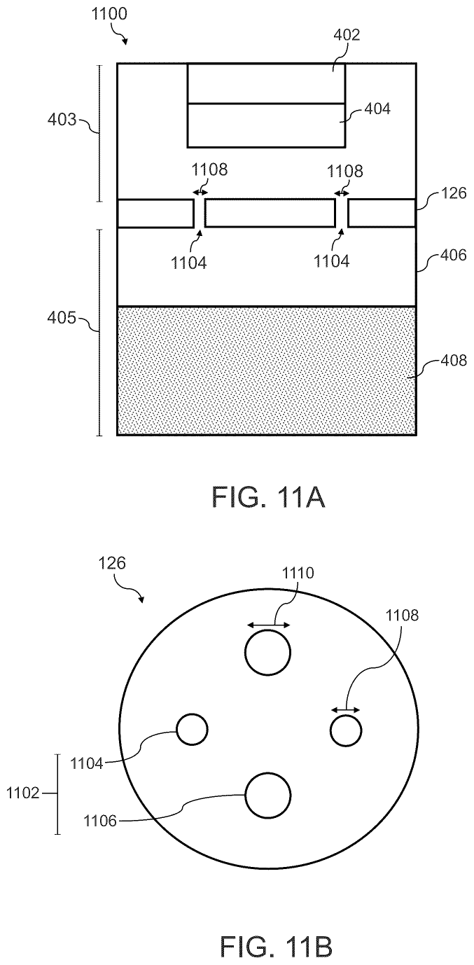

Like the crystal growth systems of FIGS. 4A-10A, the crystal growth system 1100 of FIG. 11A includes many similar components. The crystal growth system 1100 includes the baffle 126, the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the top view of the baffle 126 in FIG. 11B, the baffle 126 includes a plurality of different-sized apertures 1102 (e.g., including a small aperture 1104 and a large aperture 1106) defined through a thickness of the baffle 126. The plurality of different-sized apertures 1102 are depicted as being generally circular apertures, it will be understood that the small aperture 1104 and/or the large aperture 1106 may include any suitable shape or configuration, such as a generally square shape, a generally rectangular shape, a generally triangular shape, etc.

The plurality of different-sized apertures 1102 may be positioned such that the plurality of different-sized apertures 1102 may provide a linear pathway for the transport of source vapor unimpeded by the material of the baffle 126 to travel to peripheral portions of the seed crystal 404 at different rates. For instance, the rate of source vapor traveling through the small aperture 1104 will be different than the rate of source vapor travelling through the large aperture 1106, which will also differ from the rate of source vapor travelling (e.g., diffusing) through the material of the baffle 126. The small aperture(s) 1104 of the plurality of different-sized apertures 1102 are depicted as being narrow apertures with a width 1108, whereas the large apertures 1106 are depicted with a comparatively larger width 1110. That is, the width 1108 of the first aperture (e.g., the small aperture 1104) is different from the width 1110 of the second aperture (e.g., the large aperture 1106). The plurality of different-sized apertures 1102 may have any suitable width (e.g., diameter) such that the small aperture(s) 1104 and the large apertures 1106 have the widths 1108, 1110 that are about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm.

The plurality of different-sized apertures 1102 may provide a direct path (e.g., a path between the upper portion 403 and the lower portion 405 of the crystal growth chamber that is linear or otherwise unobstructed) through the baffle 126 for transport of vapor from the source material 408 to the seed crystal 404 without having significant crystal growth formation in the plurality of apertures 1002.

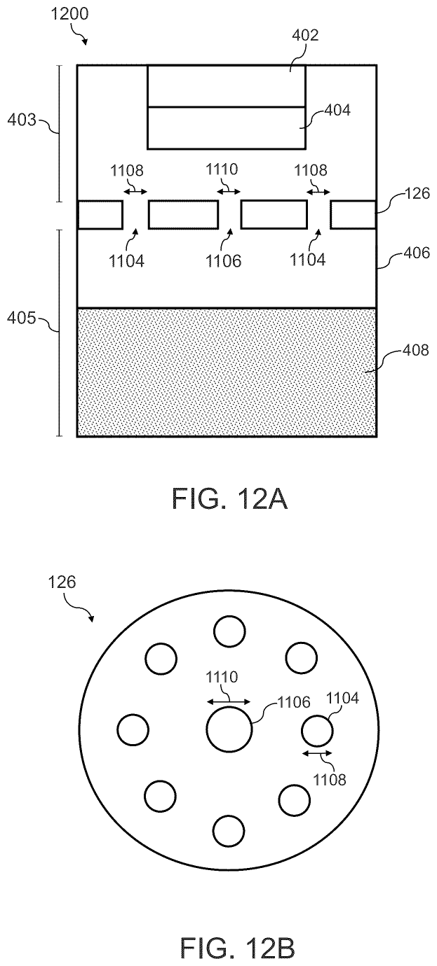

Like the crystal growth systems of FIGS. 4A-11A, the crystal growth system 1200 of FIG. 12A includes many similar components. The crystal growth system 1200 includes the baffle 126, the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the top view of the baffle 126 in FIG. 12B, the baffle 126 includes a concentric ring of small apertures 1104 with the width 1108 surrounding the large aperture 1106 with the width 1110. That is, the small apertures 1104 have a density (e.g., occurrence) in the baffle 126 that is different from a density (e.g., occurrence) of the large aperture 1106 in the baffle 126. In some embodiments, the small apertures 1104 (e.g., a plurality of small apertures 1104) may be in the central portion of the baffle 126 and the large apertures 1106 (e.g., a plurality of large apertures 1106) may be on a peripheral portion of the baffle 126. In the example depicted in FIG. 12B, the small apertures 1104 and the large aperture 1106 are depicted as circular apertures, it will be understood that the small apertures 1104 and/or the large aperture 1106 may include any suitable shape or configuration, such as a generally square shape, a generally rectangular shape, a generally triangular shape, etc.

The small apertures 1104 and the large aperture 1106 may be positioned such that the small apertures 1104 and the large aperture 1106 provide a linear pathway for the transport of source vapor unimpeded by the material of the baffle 126 to travel to central and sidewall portions of the seed crystal 404 at different rates. For instance, the rate of source vapor traveling through the small aperture 1104 will be different than the rate of source vapor travelling through the large aperture 1106, which will also differ from the rate of source vapor travelling (e.g., diffusing) through the material of the baffle 126. The small aperture(s) 1104 are depicted as being narrow apertures with a width 1108, whereas the large apertures 1106 are depicted with a comparatively larger width 1110. That is, the width 1108 of the first aperture (e.g., the small aperture 1104) is different from the width 1110 of the second aperture (e.g., the large aperture 1106). The small apertures 1104 and/or the large aperture 1106 may have any suitable width (e.g., diameter) such that the small aperture(s) 1104 and the large aperture 1106 have the widths 1108, 1110 that are about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. The small apertures 1104 and the large aperture 1106 may provide a direct path (e.g., a path between the upper portion 403 and the lower portion 405 of the crystal growth chamber that is linear or otherwise unobstructed) through the baffle 126 for transport of vapor from the silicon carbide vapor source material 408 to the seed crystal 404 without having significant crystal growth formation in either of the small apertures 1104 or the large apertures 1106. The small apertures 1104 and the large aperture 1106 are positioned under the central and sidewall portions of the seed crystal 404 for discussion purposes only, the small apertures 1104 and/or the large aperture 1106 may be positioned under the peripheral portion of the seed crystal 404, the sidewall of the seed crystal 404 and/or the central portion of the seed crystal 404.

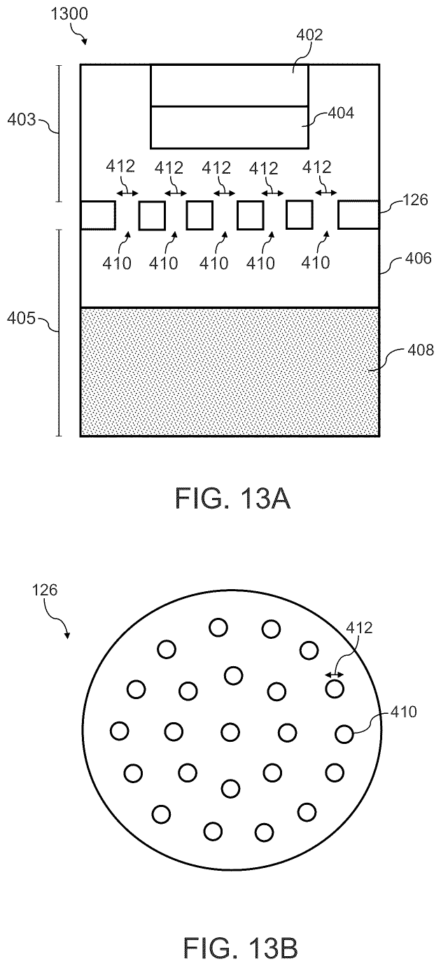

Like the crystal growth systems of FIGS. 4A-12A, the crystal growth system 1300 of FIG. 13A includes many similar components. The crystal growth system 1300 includes the baffle 126, the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the top view of the baffle 126 in FIG. 13B, the baffle 126 includes one or more concentric rings of the apertures 410 with the width 412. The apertures 410 are depicted as circular apertures, it will be understood that the apertures 410 may include any suitable shape or configuration, such as a generally square shape, a generally rectangular shape, a generally triangular shape, etc. The apertures 410 may be positioned such that the apertures 410 provide a linear pathway for the transport of source vapor unimpeded by the material of the baffle 126 to travel to central and peripheral portions of the seed crystal 404. The apertures 410 are depicted as being narrow apertures with a width 412. The apertures 410 may have any suitable width (e.g., diameter) such that the apertures 410 have the width 412 that is about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. The apertures 410 may provide a direct path (e.g., a path between the upper portion 403 and the lower portion 405 of the crystal growth chamber that is linear or otherwise unobstructed) through the baffle 126 for transport of vapor from the silicon carbide vapor source material 408 to the seed crystal 404 without having significant crystal growth formation in the apertures 410.

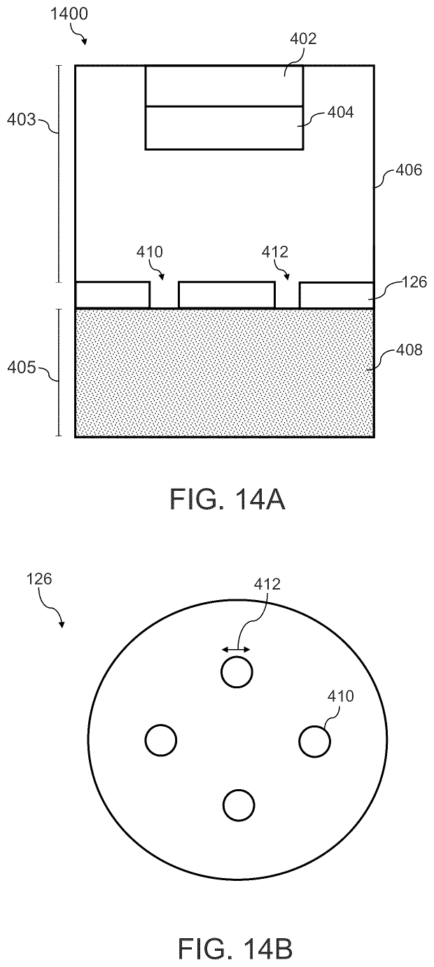

Like the crystal growth systems of FIGS. 4A-13A, the crystal growth system 1400 of FIG. 14A includes many similar components. The crystal growth system 1400 includes the baffle 126, the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406. In some examples the baffle 126 may be directly adjacent to the source material 408 such that there is no separation between the baffle 126 and the source material 408. The baffle 126, as depicted in the top view of the baffle 126 in FIG. 14B, is depicted as being the baffle 126 of FIG. 10B for purposes of discussion only. The baffle 126 may be any of the baffles contemplated by the present disclosure.

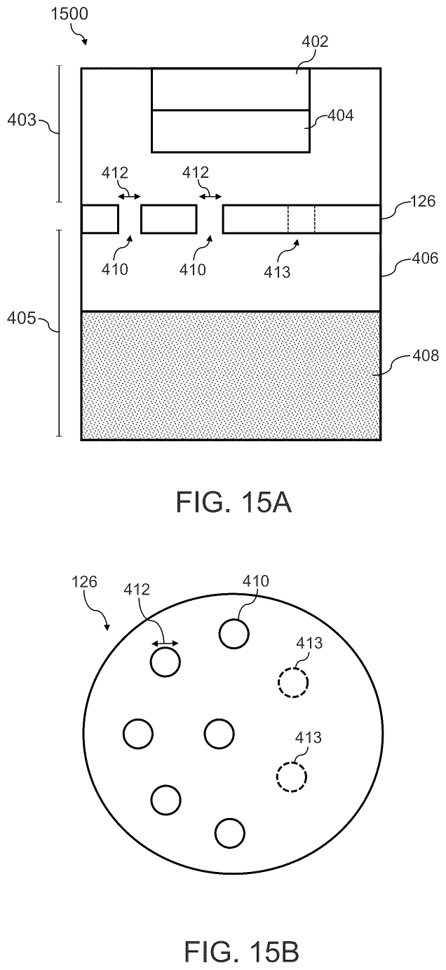

Like the crystal growth systems of FIGS. 4A-14A, the crystal growth system 1500 of FIG. 15A includes many similar components. The crystal growth system 1500 includes the baffle 126, the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the top view of the baffle 126 in FIG. 15B, the baffle 126 includes the apertures 410 with the width 412 that are positioned asymmetrically on the baffle 126, such that no apertures are present on at least portion of the baffle 126. The apertures 410 are depicted as circular apertures, it will be understood that the apertures 410 may include any suitable shape or configuration, such as a generally square shape, a generally rectangular shape, a generally triangular shape, etc. The apertures 410 may be positioned such that the apertures 410 provide a linear pathway for the transport of source vapor unimpeded by the material of the baffle 126 to travel to central and peripheral portions of one half of the seed crystal 404.

The asymmetric configuration of the apertures 410 on the baffle 126 may provide for asymmetric crystal growth on the seed crystal 404. The apertures 410 are depicted as being narrow apertures with a width 412. The apertures 410 may have any suitable width (e.g., diameter) such that the apertures 410 have the width 412 that is about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. The apertures 410 may provide a direct path (e.g., a path between the upper portion 403 and the lower portion 405 of the crystal growth chamber that is linear or otherwise unobstructed) through the baffle 126 for transport of vapor from the silicon carbide vapor source material 408 to the seed crystal 404 without having significant crystal growth formation in the apertures 410.

As illustrated in FIG. 15B, the baffle 126 may include one or more optional apertures 413. The optional apertures 413 may be less in density on the right side of the baffle 126 relative to the left side of the baffle 126. The baffle 126, even with optional apertures, may provide asymmetric vapor transport to the seed crystal 404.

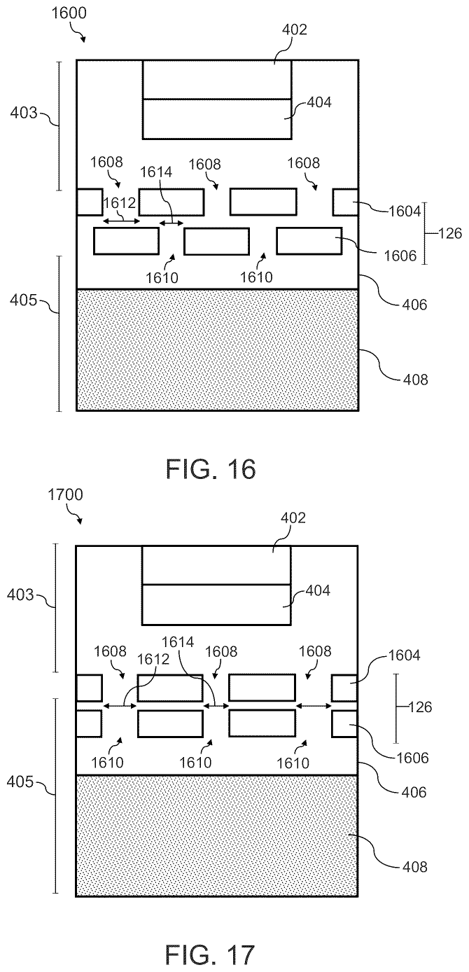

Like the crystal growth systems of FIGS. 4A-15A, the crystal growth system 1600 of FIG. 16 includes many similar components. The crystal growth system 1600 includes the baffle 126 including a plurality of baffle plates (e.g., a first baffle plate 1604 and a second baffle plate 1606). The first baffle plate 1604 and the second baffle plate 1606 may be any of the baffles 126 as contemplated by present disclosure. The crystal growth system 1600 may include the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, at least one of the baffle plates 1604, 1606 may not fully extend between the inner walls of the crucible 406.

As depicted in the simplified view of the crystal growth system 1600 of FIG. 16, the first baffle plate 1604 and the second baffle plate 1606 define openings having a circuitous path for vapor transport. As used herein, a circuitous path refers to a non-linear path. For instance, the baffle 126 may impede or otherwise obstruct a linear path that source vapor may travel from the source material 408 to the seed crystal 404. That is, a first aperture 1608 on the first baffle plate 1604 may not align with a second aperture 1610 on the second baffle plate 1606. In some examples, such as the example depicted in FIG. 16, the first aperture(s) 1608 may have a different width 1612 relative to a width 1614 of the second aperture 1610. In some examples, the width 1612 of the first aperture(s) 1608 on the first baffle plate 1604 may be the same as the width 1614 of the second aperture 1610 on the second baffle plate 1606. By varying the widths 1612, 1614 of the first aperture 1608 on the first baffle plate 1604 and the second aperture 1610 on the second baffle plate 1606, the rate of source vapor or other process gases transported to the seed crystal 404 may be modified to suit a crystal growth process. Further, modifications to the transport path (e.g., shortening, elongating, etc.) of the source vapor or other process gases may alter the thermodynamic and kinetic factors that drive diffusion, which may provide control over crystal growth on the seed crystal 404.

Like the crystal growth systems of FIGS. 4A-16, the crystal growth system 1700 of FIG. 17 includes many similar components. The crystal growth system 1700 includes the baffle 126 including a plurality of baffle plates (e.g., the first baffle plate 1604 and the second baffle plate 1606). The first baffle plate 1604 and the second baffle plate 1606 may be any of the baffles 126 as contemplated by the present disclosure. The crystal growth system 1700 may include the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in the simplified view of the crystal growth system 1700 of FIG. 17, the baffle 126 including a plurality of baffle plates (e.g., the first baffle plate 1604 and the second baffle plate 1606) may not impede or otherwise obstruct a linear path that source vapor may travel from the source material 408 to the seed crystal 404. That is, the first aperture 1608 on the first baffle plate 1604 may align with the second aperture 1610 on the second baffle plate 1606. In some examples, such as the example depicted in FIG. 17, the first aperture(s) 1608 may have the same width 1612 relative to the width 1614 of the second aperture 1610. In some examples, the width 1612 of the first aperture 1608 on the first baffle plate 1604 may differ from the width 1614 of the second aperture 1610 on the second baffle plate 1606, while maintaining, at least partially, a linear path from the source material 408 to the seed crystal 404. The first aperture 1608 and the second aperture 1610 may have any suitable width (e.g., diameter) such that the widths 1612, 1614 are about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. By varying the widths 1612, 1614 of the first aperture 1608 on the first baffle plate 1604 and the second aperture 1610 on the second baffle plate 1606, the rate of source vapor or other process gases transported to the seed crystal 404 may be modified to suit a crystal growth process. Further, modifications to the transport path (e.g., shortening, elongating, etc.) of the source vapor or other process gases may alter the thermodynamic and kinetic factors that drive diffusion, providing more control over crystal growth on the seed crystal 404.

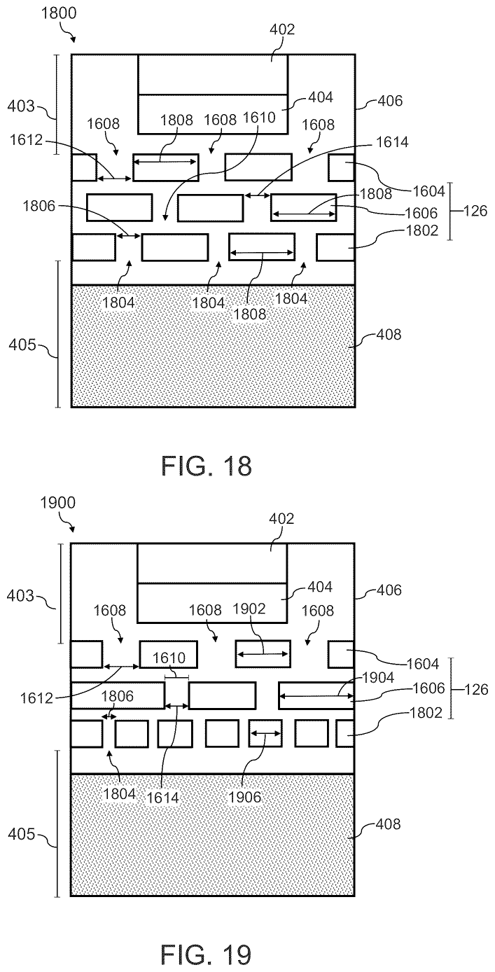

Like the crystal growth systems of FIGS. 4A-17, the crystal growth system 1800 of FIG. 18 includes many similar components. The crystal growth system 1800 includes the baffle 126 including a plurality of baffle plates (e.g., the first baffle plate 1604, the second baffle plate 1606, and a third baffle plate 1802). The first baffle plate 1604, the second baffle plate 1606, and the third baffle plate 1802 may be any of the baffles 126 as contemplated by the present disclosure. The crystal growth system 1800 may include the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, baffle 126 may not fully extend between the inner walls of the crucible 406.

As depicted in the example represented in FIG. 18, the first baffle plate 1604, the second baffle plate 1606, and the third baffle plate 1802 define openings having a circuitous path for vapor transport. For instance, the baffle 126 may impede or otherwise obstruct a linear path that source vapor may travel from the source material 408 to the seed crystal 404. That is, the first aperture 1608 on the first baffle plate 1604 may not align with the second aperture 1610 on the second baffle plate 1606, which may not align with a third aperture 1804 on the third baffle plate 1802. In some embodiments, the width 1612 of the first aperture(s) 1608 may differ relative to the width 1614 of the second aperture 1610, which may differ from the width 1806 of the third aperture.

In some examples, the width 1612 of the first aperture(s) 1608 on the first baffle plate 1604 may be the same as the width 1614 of the second aperture 1610 on the second baffle plate 1606 or the width 1806 of the third aperture 1804 on the third baffle plate 1802. The first aperture 1608, the second aperture 1610, and/or the third aperture 1804 may have any suitable width (e.g., diameter) such that the widths 1612, 1614, 1806 are about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. By varying the widths 1612, 1614, 1806 of the first aperture 1608 on the first baffle plate 1604, the second aperture 1610 on the second baffle plate 1606, and the third aperture 1804 on the third baffle plate 1802, the rate of source vapor or other process gases transported to the seed crystal 404 may be modified to suit a crystal growth process. Further, modifications to the transport path (e.g., shortening, elongating, etc.) of the source vapor or other process gases may alter the thermodynamic and kinetic factors that drive diffusion, providing more control over crystal growth on the seed crystal 404.

As depicted in FIG. 18, the first aperture 1608, the second aperture 1610, and the third aperture 1804 may have a similar spacing 1808 on the first baffle plate 1604, the second baffle plate 1606, and the third baffle plate 1802. The spacing 1808 may be any suitable dimension (e.g., width) to provide the first aperture 1608, the second aperture 1610, and the third aperture 1804 on the first baffle plate 1604, the second baffle plate 1606, and the third baffle plate 1802 at regular intervals.

Like the crystal growth systems of FIGS. 4A-18, the crystal growth system 1900 of FIG. 19 includes many similar components. The crystal growth system 1900 includes the baffle 126 including a plurality of baffle plates (e.g., the first baffle plate 1604, the second baffle plate 1606, and the third baffle plate 1802). The first baffle plate 1604, the second baffle plate 1606, and the third baffle plate 1802 may be any of the baffles 126 as contemplated by the present disclosure. The crystal growth system 1900 may include the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, baffle 126 may not fully extend between the inner walls of the crucible 406.

As depicted in the embodiment represented in FIG. 19, the first baffle plate 1604, the second baffle plate 1606, and the third baffle plate 1802 define openings having a circuitous path for vapor transport. For instance, the baffle 126 may impede or otherwise obstruct a linear path that source vapor may travel from the source material 408 to the seed crystal 404. That is, the first aperture 1608 on the first baffle plate 1604 may not align with the second aperture 1610 on the second baffle plate 1606, which may not align with the third aperture 1804 on the third baffle plate 1802. In some examples, such as the example depicted in FIG. 19, the width 1612 of the first aperture(s) 1608 may differ relative to the width 1614 of the second aperture 1610, which may differ from the width 1806 of the third aperture 1804.

In some examples, the width 1612 of the first aperture(s) 1608 on the first baffle plate 1604 may be the same as the width 1614 of the second aperture 1610 on the second baffle plate 1606 or the width 1806 of the third aperture 1804 on the third baffle plate 1802. The first aperture 1608, the second aperture 1610, and/or the third aperture 1804 may have any suitable width (e.g., diameter) such that the widths 1612, 1614, 1806 are about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. By varying the widths 1612, 1614, 1806 of the first aperture 1608 on the first baffle plate 1604, the second aperture 1610 on the second baffle plate 1606, and the third aperture 1804 on the third baffle plate 1802, the rate of source vapor or other process gases transported to the seed crystal 404 may be modified to suit a crystal growth process. Further, modifications to the transport path (e.g., shortening, elongating, etc.) of the source vapor or other process gases may alter the thermodynamic and kinetic factors that drive diffusion, providing more control over crystal growth on the seed crystal 404.

As depicted in FIG. 19, the first aperture 1608, the second aperture 1610, and the third aperture 1804 may have a dissimilar spacing 1902 on the first baffle plate 1604, a dissimilar spacing 1904 on the second baffle plate 1606, and a dissimilar spacing 1906 on the third baffle plate 1802. The dissimilar spacing 1902, 1904, 1906 may be any suitable dimension to provide the first aperture 1608, the second aperture 1610, and the third aperture 1804 on the first baffle plate 1604, the second baffle plate 1606, and the third baffle plate 1802 at irregular, nonlinear intervals.

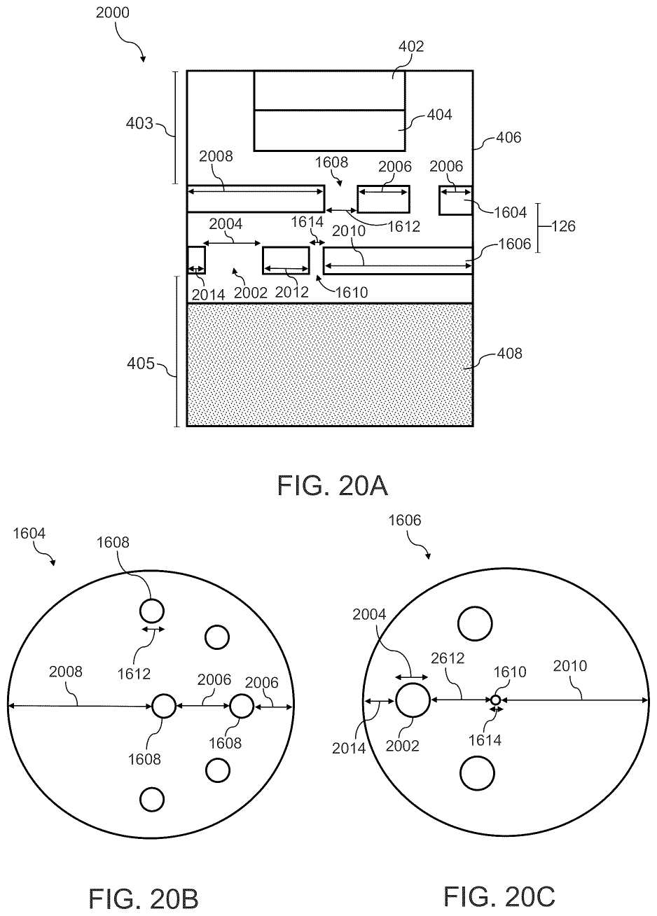

Like the crystal growth systems of FIGS. 4A-19, the crystal growth system 2000 of FIG. 20A includes many similar components. The crystal growth system 2000 includes the baffle 126 including a plurality of baffle plates (e.g., the first baffle plate 1604 and the second baffle plate 1606). Although two baffle plates are depicted in FIG. 20A, it will be understood that the baffle 126 of FIG. 20A may include any number of baffle plates as needed to alter the transport path of source vapor in the crystal growth system 2000. The first baffle plate 1604 and the second baffle plate 1606 may be any of the baffles 126 as contemplated by the present disclosure. The crystal growth system 2000 may include the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, baffle 126 may not fully extend between the inner walls of the crucible 406.

As depicted in the embodiment represented in FIG. 20A, the baffle 126 may define one or more opening having a circuitous path for vapor transport. For instance, the baffle 126 may impede or otherwise obstruct a linear path that source vapor may travel from the source material 408 to the seed crystal 404. That is, one or more of the first apertures 1608 on the first baffle plate 1604 may not align with the second aperture 1610 on the second baffle plate 1606, which may not align with a third aperture 2002 on the second baffle plate 1606. As depicted in FIG. 20A, the width 1612 of the first aperture(s) 1608 may differ relative to the width 1614 of the second aperture 1610 on the second baffle plate 1606, which may differ from the width 2004 of the third aperture 2002 on the second baffle plate 1606. In some embodiments, the width 1612 of the first aperture(s) 1608 on the first baffle plate 1604 may be the same as the width 1614 of the second aperture 1610 on the second baffle plate 1606 and/or the width 2004 of the third aperture 2002 on the second baffle plate 1606. The first apertures 1608, the second apertures 1610, and/or the third apertures 2002 may have any suitable width (e.g., diameter) such that the widths 1612, 1614, 2004 are about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. By varying the widths 1612, 1614, 2004 of the first aperture 1608 on the first baffle plate 1604, the second aperture 1610 on the second baffle plate 1606, and the third aperture 2002 on the second baffle plate 1606, the rate of source vapor or other process gases transported to the seed crystal 404 may be modified to suit a crystal growth process. Further, modifications to the transport path (e.g., shortening, elongating, etc.) of the source vapor or other process gases may alter the thermodynamic and kinetic factors that drive diffusion, providing more control over crystal growth on the seed crystal 404.

As depicted in FIG. 20A, the first apertures 1608 on the first baffle plate 1604 may have a similar spacing 2006 and a dissimilar spacing 2008, such that source vapor is transported through the first baffle plate 1604 asymmetrically and at differing rates (e.g., flowing through the aperture 1608 and diffusing through the baffle plate 1604). The second baffle plate 1606 may have one or more dissimilar spacings 2010, 2012, 2014 such that source vapor is transported through the second baffle plate 1606 asymmetrically and at differing rates (e.g., flowing through the aperture 2002 and diffusing through the baffle plate 1606) that differ from the first baffle plate 1604. The dissimilar spacing 2008 of the first baffle plate 1604 and/or the dissimilar spacing 2010, 2012, 2014 of the second baffle plate 1606 may be any suitable dimension to provide the first apertures 1608 on the first baffle plate 1604 and the second aperture 1610 and the third aperture 2002 on the second baffle plate 1606.

The top view of the first baffle plate 1604 of FIG. 20B is depicted as being the baffle 126 of FIG. 15B (e.g., the example lacking the apertures 413) rotated 180 degrees for the purposes of discussion only. Any of the baffles 126 contemplated by the present disclosure may be used as the first baffle plate 1604 such that the baffle 126 can be configured to provide an asymmetric source vapor path. Similarly, the top view of the second baffle plate 1606 of FIG. 20C is depicted with the dissimilar spacings 2010, 2012, 2014 between the second aperture 1610 and the third aperture 2002. Any configuration of the second aperture 1610 and the third aperture 2002 as contemplated by the present disclosure may be used as the second baffle plate 1606 such that the second baffle plate 1606 can be configured to provide an asymmetric source vapor path relative to the first baffle plate 1604 of FIGS. 20A and 20B. An asymmetric vapor path may transport source vapor, for instance, to the center and the sidewall (e.g., a portion outside of the edge of the seed crystal 404) of the seed crystal 404 as depicted in FIG. 20A. In some embodiments, the asymmetric vapor path may transport source vapor to the sidewall of the seed crystal 404, a peripheral portion of the seed crystal 404, or a combination of the sidewall, a peripheral portion, or a central portion of the seed crystal 404.

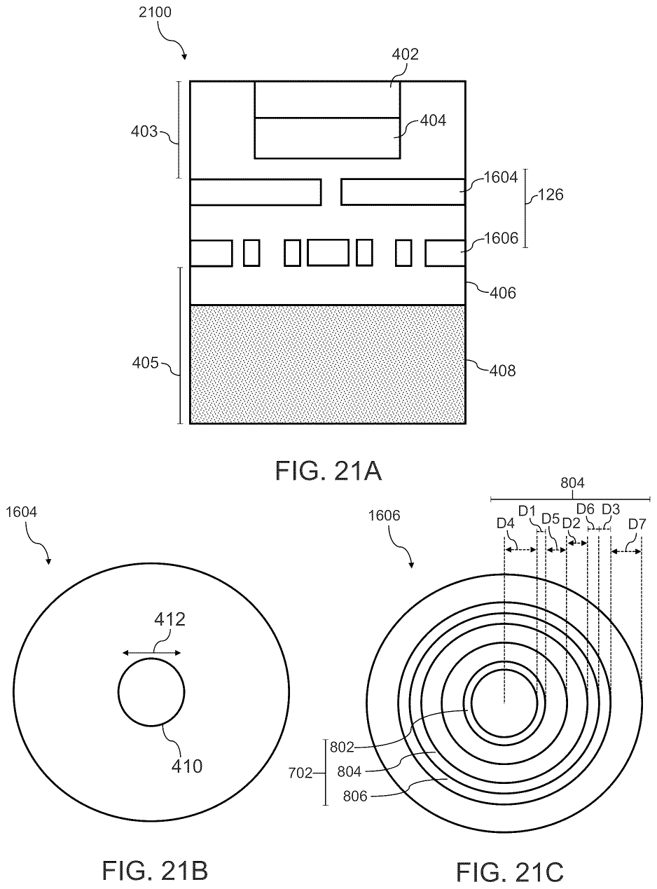

Like the crystal growth systems of FIGS. 4A-20A, the crystal growth system 2100 of FIG. 21A includes many similar components. The crystal growth system 2100 includes the baffle 126 including a plurality of baffle plates (e.g., the first baffle plate 1604 and the second baffle plate 1606). Although two baffle plates are depicted in FIG. 20A, it will be understood that the baffle 126 of FIG. 20A may include any number of baffle plates as needed to alter the transport path of source vapor in the crystal growth system 2100. As depicted in FIGS. 21B and 21C, the baffle 126 of FIG. 4B is the first baffle plate 1604 and the baffle 126 of FIG. 8B is the second baffle plate 1606. Any of the baffles contemplated by the present disclosure may be used as the first baffle plate 1604 or the second baffle plate 1606, such that the configuration of the baffle 126 as depicted in FIG. 21A transports source vapor to a central portion of the seed crystal 404. The crystal growth system 2100 may include the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, baffle 126 may not fully extend between the inner walls of the crucible 406.

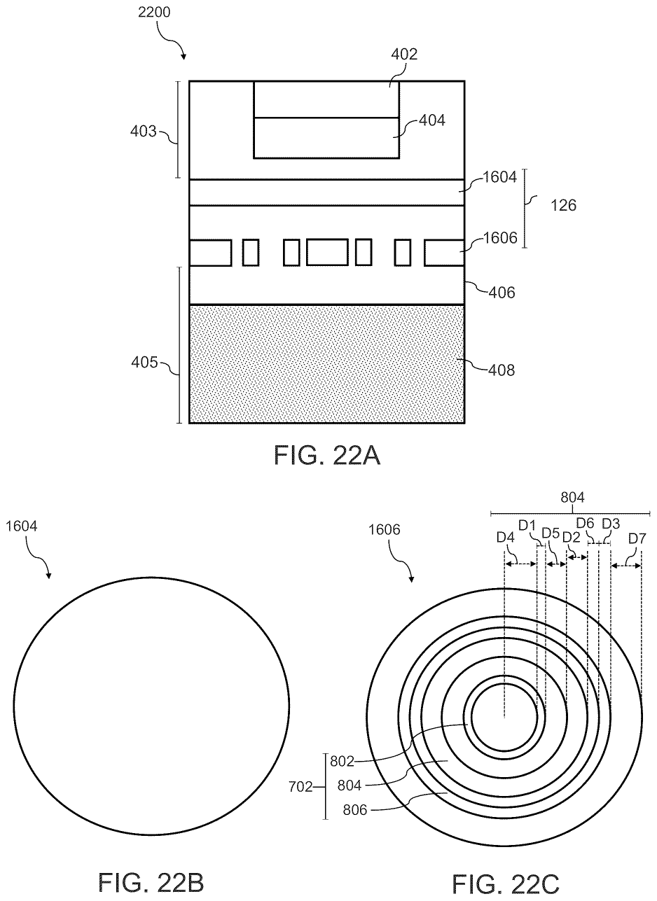

Like the crystal growth systems of FIGS. 4A-21A, the crystal growth system 2200 of FIG. 22A includes many similar components. The crystal growth system 2200 includes the baffle 126 including a plurality of baffle plates (e.g., the first baffle plate 1604 and the second baffle plate 1606). Although two baffle plates are depicted in FIG. 22A, it will be understood that the baffle 126 of FIG. 22A may include any number of baffle plates as needed to alter the transport path of source vapor in the crystal growth system 2200. The second baffle plate 1606 may be any of the baffles 126 as contemplated by the present disclosure. For instance, as depicted in FIG. 21C, the baffle 126 of FIG. 8B is the second baffle plate 1606. The crystal growth system 2200 may include the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, baffle 126 may not fully extend between the inner walls of the crucible 406.

As depicted in the top view of the first baffle plate 1604 in FIG. 22B, the first baffle plate 1604 may not include any apertures. The first baffle plate 1604 may rely on diffusion of source vapor through the material of the first baffle plate 1604 to transport source vapor to the seed crystal 404.

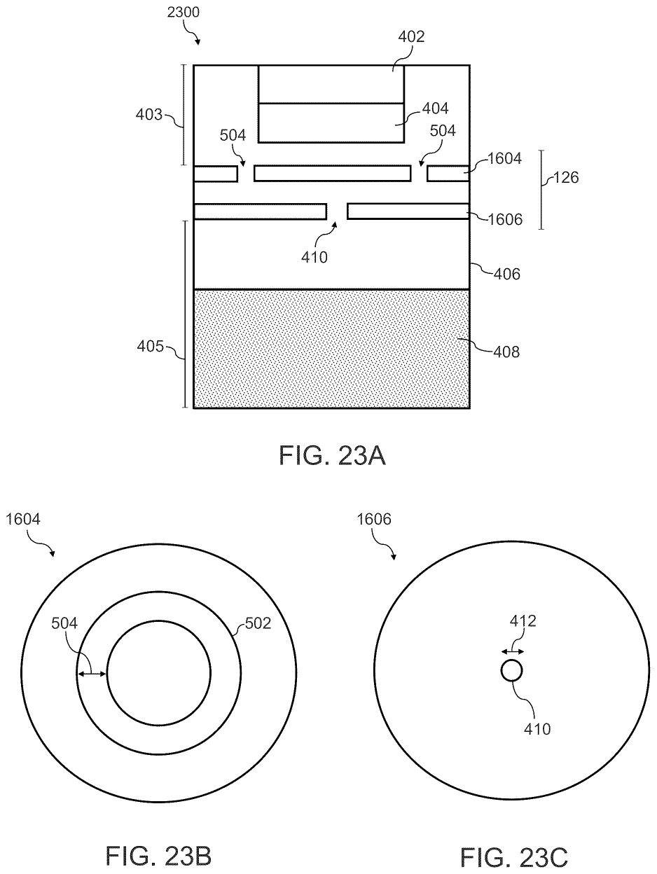

Like the crystal growth systems of FIGS. 4A-22A, the crystal growth system 2300 of FIG. 23A includes many similar components. The crystal growth system 2300 includes the baffle 126 including a plurality of baffle plates (e.g., the first baffle plate 1604 and the second baffle plate 1606). Although two baffle plates are depicted in FIG. 23A, it will be understood that the baffle 126 of FIG. 20A may include any number of baffle plates as needed to alter the transport path of source vapor in the crystal growth system 2300. As depicted in FIGS. 23B and 23C, the baffle 126 of FIG. 5B is the first baffle plate 1604 and the baffle 126 of FIG. 4D is the second baffle plate 1606. Any of the baffles contemplated by the present disclosure may be used as the first baffle plate 1604 or the second baffle plate 1606, such that the configuration of the baffle 126 transports source vapor to a peripheral portion of the seed crystal 404 as depicted in FIG. 23A.

The crystal growth system 2300 may include the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, baffle 126 may not fully extend between the inner walls of the crucible 406. In some examples, at least one of the first baffle plate 1604 or the second baffle plate 1606 may be made, at least in part, of a carbon material (e.g., at least partially uncoated graphite with an exposed graphite surface) to act as a secondary source material in a crystal growth process conducted in the crystal growth system 2300.

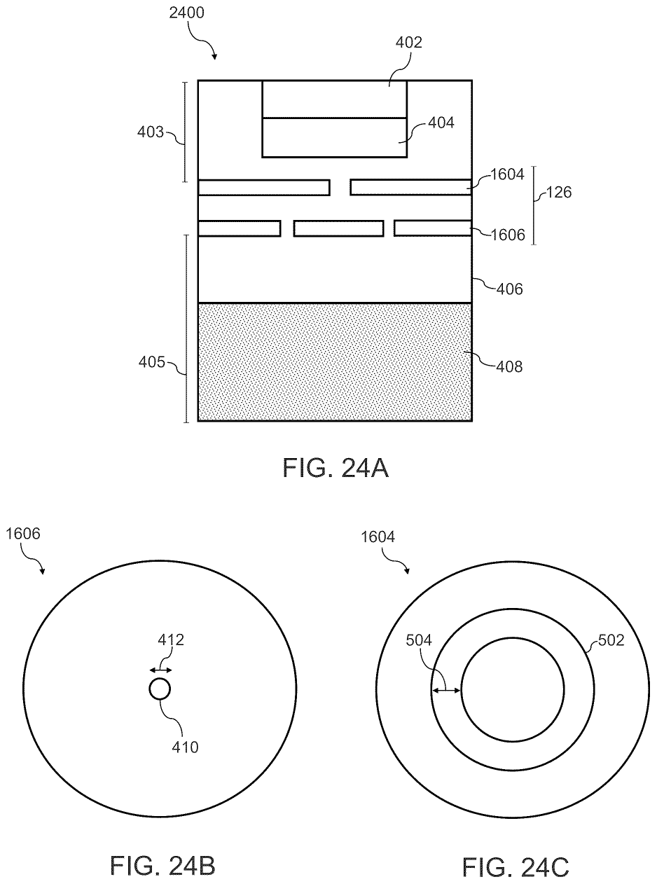

Like the crystal growth systems of FIGS. 4A-23A, the crystal growth system 2400 of FIG. 24A includes many similar components. The crystal growth system 2400 includes the baffle 126 including a plurality of baffle plates (e.g., the first baffle plate 1604 and the second baffle plate 1606). Although two baffle plates are depicted in FIG. 23A, it will be understood that the baffle 126 of FIG. 20A may include any number of baffle plates as needed to alter the transport path of source vapor in the crystal growth system 2300. As depicted in FIGS. 24B and 24C, the baffle 126 of FIG. 4D is the first baffle plate 1604 and the baffle 126 of FIG. 5B is the second baffle plate 1606. Any of the baffles contemplated by the present disclosure may be used as the first baffle plate 1604 or the second baffle plate 1606, such that the configuration of the baffle 126 as depicted in FIG. 23A transports source vapor to a central portion of the seed crystal 404. The crystal growth system 2400 may include the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, baffle 126 may not fully extend between the inner walls of the crucible 406. In some examples, at least one of the first baffle plate 1604 or the second baffle plate 1606 may be, at least in part, silicon carbide to act as a secondary source material in a crystal growth process conducted in the crystal growth system 2400.

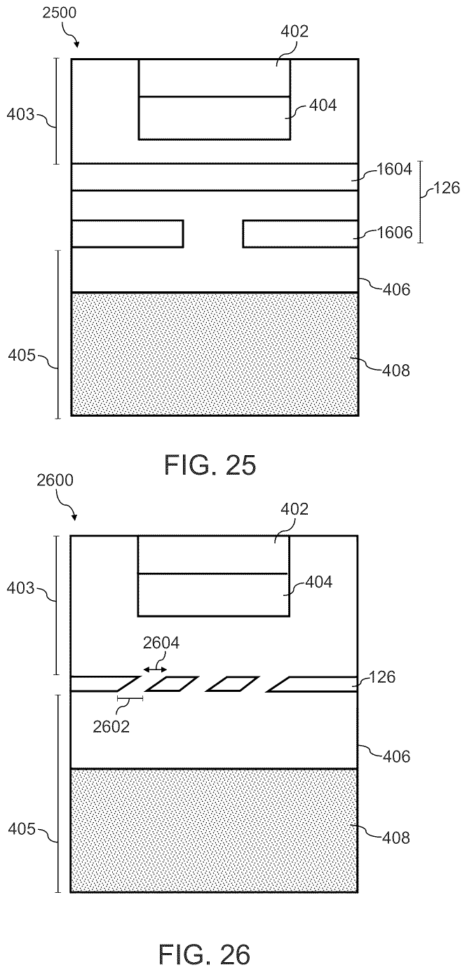

Like the crystal growth systems of FIGS. 4A-24A, the crystal growth system 2500 of FIG. 25 includes many similar components. The crystal growth system 2500 includes the baffle 126 including a plurality of baffle plates (e.g., the first baffle plate 1604 and the second baffle plate 1606). Although two baffle plates are depicted in FIG. 25, it will be understood that the baffle 126 of FIG. 25 may include any number of baffle plates as needed to alter the transport path of source vapor in the crystal growth system 2500. The crystal growth system 2500 may include the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, baffle 126 may not fully extend between the inner walls of the crucible 406.

The first baffle plate 1604 may provide for transport of source vapor through the material of the first baffle plate 1604 to transport source vapor to the seed crystal 404. In some examples, at least one of the first baffle plate 1604 or the second baffle plate 1606 may be, at least in part, a carbon material (e.g., at least partially uncoated graphite with an exposed graphite surface) to act as a secondary source material in a crystal growth process conducted in the crystal growth system 2300. In some examples, at least one of the first baffle plate 1604 or the second baffle plate 1606 may be, at least in part, silicon carbide to act as a secondary source material in a crystal growth process conducted in the crystal growth system 2400.

Like the crystal growth systems of FIGS. 4A-25, the crystal growth system 2600 of FIG. 26 includes many similar components. The crystal growth system 2600 includes the baffle 126, the seed holder 402, the seed crystal 404, the crucible 406, and the source material 408. In some embodiments, the baffle 126 may extend between the inner walls of the crucible 406, such that the crucible 406 is bisected or divided into an upper portion 403 and a lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

As depicted in FIG. 26, the baffle 126 may include one or more oblique (e.g., non-perpendicular to growth surface of the seed crystal) apertures 2602 with the width 2604. It will be understood that the apertures 2602 may include any suitable shape or configuration, such as a generally square shape, a generally rectangular shape, a generally triangular shape, etc. The apertures 2602 may be positioned such that the apertures 2602 provide a vapor transport direction in a non-perpendicular direction relative to the growth surface of the seed crystal 404. The apertures 2602 are depicted as being narrow apertures with the width 2604. The apertures 2602 may have any suitable width (e.g., diameter) such that the apertures 2602 have the width 2604 that is about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm. The apertures 2602 may provide a direct path (e.g., a path between the upper portion 403 and the lower portion 405 of the crystal growth chamber that is linear or otherwise unobstructed) through the baffle 126 for transport of vapor from the silicon carbide vapor source material 408 to the seed crystal 404 without having significant crystal growth formation in the apertures 2602.

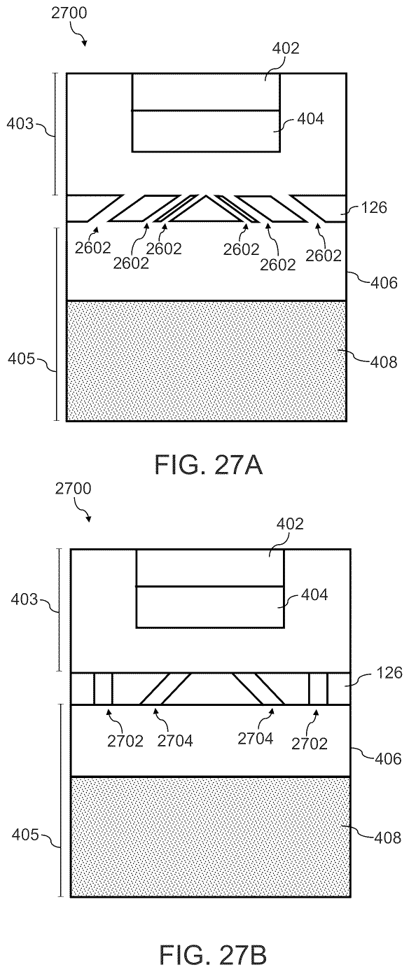

The apertures 2602 are depicted as having a series of parallel oblique slants to the right for purposes of discussion only. It will be understood that the apertures 4602 may have an oblique slant to the left, or a combination of oblique slants to the left and to the right, to alter the vapor transport path to the seed crystal 404. For instance, as depicted in FIG. 27A, the apertures 2602 are depicted as having a left oblique slant and a right oblique slant that direct source vapor towards a central portion of the seed crystal 404. In some examples, the apertures 2602 may include a combination of oblique slants that direct source vapor toward a peripheral portion and/or a sidewall portion of the seed crystal 404.

In some embodiments, as shown in FIG. 27B, the apertures may have different angles. For instance, one or more first apertures may have a first angle relative to a growth surface of the seed crystal 404 and or more second apertures may have a second angle relative to the growth surface of the seed crystal 404. The second angle can be different from the first angle. For instance, the baffle 126 may have apertures 2702 that are generally perpendicular to the growth surface of the seed crystal 404. The baffle 126 may have apertures 2704 that are non-perpendicular to the growth surface of the seed crystal 404.

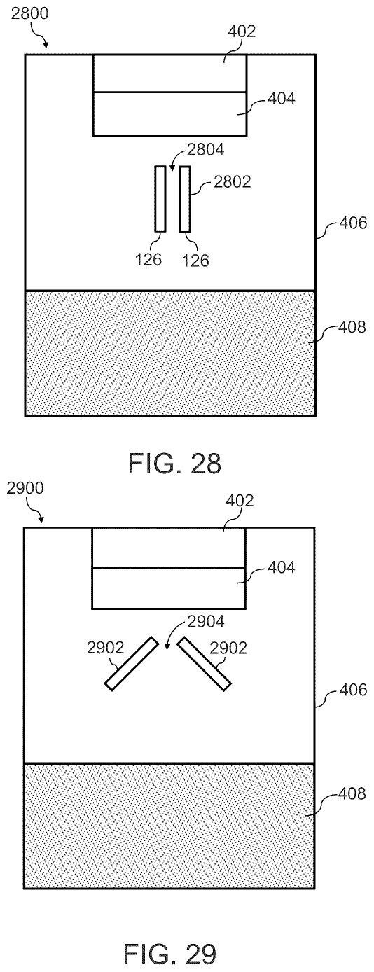

Like the crystal growth systems of FIGS. 4A-27, the crystal growth system 2800 of FIG. 28 includes many similar components. The crystal growth system 2800 includes the baffle 126, the seed holder 402, the seed crystal 404, the crucible 406, and the source material 408. The baffle 126 includes a tubular baffle structure having a sidewall 2802 that forms a channel-like aperture 2804. The sidewall 2802 of the baffle 126 may form a tubular structure (e.g., cylindrical tube). The sidewall 2802 may be generally perpendicular to a growth surface of the seed crystal 404. Further, the baffle 126 is depicted as overlapping a central portion of the seed crystal 404. The baffle 126 may be positioned in any spatial relation to the seed crystal 404, such as overlapping one or more peripheral portions of the seed crystal 404, overlapping one or more sidewall portions of the seed crystal 404, or in closer proximity to the source material 408 relative to the proximity of the baffle 126 to the seed crystal 404, and so forth. In some examples, the baffle 126 may be coupled to a side wall of the crucible 406.

The baffle 126 may slow down vapor transport in the central portion of the seed crystal 404 relative to the peripheral portion of the seed crystal 404 to compensate for non-uniform growth of the seed crystal in the absence of the baffle 126. For instance, when a crystal is grown, there may be thermal stresses induced in the crystal due to non-uniform changes in thermal gradients within the crystal. For successful PVT growth, a concave temperature profile (e.g., cooler in the central portion of the seed crystal 404 with respect to a peripheral portion of the seed crystal 404) may be applied to the growth surface to allow for convex curvature of the crystal growth interface (e.g., the crystal grows faster at the central portion where temperature is slightly lower than the peripheral portion of the seed crystal due to thermal gradients in the area). The baffle 126 having the tubular structure shown in FIG. 28 may impose a concave profile on the radiation flux hitting the growth surface of the seed crystal 404. The tubular structure with aperture 2804 still allows the transport of vapor to the growth surface. The tubular baffle 126 is able to partly shadow the central portion of the seed crystal 404 but is able to transport vapor without disruption.

As described below, the tubular baffle structure according to examples of the present disclosure may take many different forms without deviating from the scope of the present disclosure. For instance, FIGS. 29-33 depict crystal growth systems with various tubular baffle structures according to examples of the present disclosure.

Like the crystal growth systems of FIGS. 4A-28, the crystal growth system 2900 of FIG. 29 includes many similar components. The crystal growth system 2800 includes the baffle 126, the seed holder 402, the seed crystal 404, the crucible 406, and the source material 408. The baffle 126 includes a tubular baffle structure having a sidewall 2902 that forms a funnel-like aperture 2904. The sidewall 2902 may be non-perpendicular to the growth surface of the seed crystal 404. For instance, the sidewall 2902 may be angled toward a central portion of the seed crystal 404.

The baffle 126 may be positioned in any spatial relation to the seed crystal 404, such as overlapping one or more peripheral portions of the seed crystal, overlapping one or more sidewall portions of the seed crystal, or in closer proximity to the source material 408 relative to the proximity of the baffle 126 to the seed crystal 404, and so forth. In some examples, the baffle 126 may be coupled to a side wall of the crucible 406.

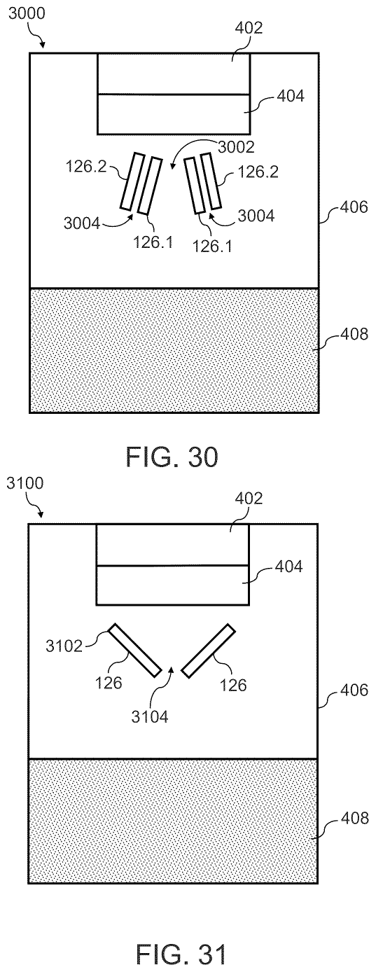

Like the crystal growth systems of FIGS. 4A-29, the crystal growth system 3000 of FIG. 30 includes many similar components. The crystal growth system 3000 includes the baffle 126, the seed holder 402, the seed crystal 404, the crucible 406, and the source material 408. The baffle 126 includes a plurality of parallel tubular structures 126.1 and 126.2. The baffle 126 includes a first aperture 3002 through a first tubular structure 126.1. The baffle 126 includes a second aperture 3004 between the first tubular structure 126.1 and the second tubular structure 126.2. The first tubular structure 126.1 and the second tubular structure 126.2 may be arranged concentrically with one another. The sidewall of both the first tubular structure 126.1 and the second tubular structure 126.2 may be non-perpendicular to the growth surface of the seed crystal 404. For instance, the sidewalls may be angled toward a central portion of the seed crystal 404.

The baffle 126 may be positioned in any spatial relation to the seed crystal 404, such as overlapping one or more peripheral portions of the seed crystal 404, overlapping one or more sidewall portions of the seed crystal 404, or in closer proximity to the source material 408 relative to the proximity of the baffle 126 to the seed crystal 404, and so forth. In some examples, the baffle 126 may be coupled to a side wall of the crucible 406.

Like the crystal growth systems of FIGS. 4A-30, the crystal growth system 3100 of FIG. 31 includes many similar components. The crystal growth system 3100 includes the baffle 126, the seed holder 402, the seed crystal 404, the crucible 406, and the source material 408. The baffle 126 includes a tubular baffle structure 126 having a sidewall 3102 that forms a funnel-like aperture 3104. The sidewall 3102 may be non-perpendicular to the growth surface of the seed crystal 404. For instance, the sidewall 3102 may be angled toward a peripheral portion of the seed crystal 404.

The baffle 126 may be positioned in any spatial relation to the seed crystal 404, such as overlapping one or more peripheral portions of the seed crystal, overlapping one or more sidewall portions of the seed crystal, or in closer proximity to the source material 408 relative to the proximity of the baffle 126 to the seed crystal 404, and so forth. In some examples, the baffle 126 may be coupled to a side wall of the crucible 406.

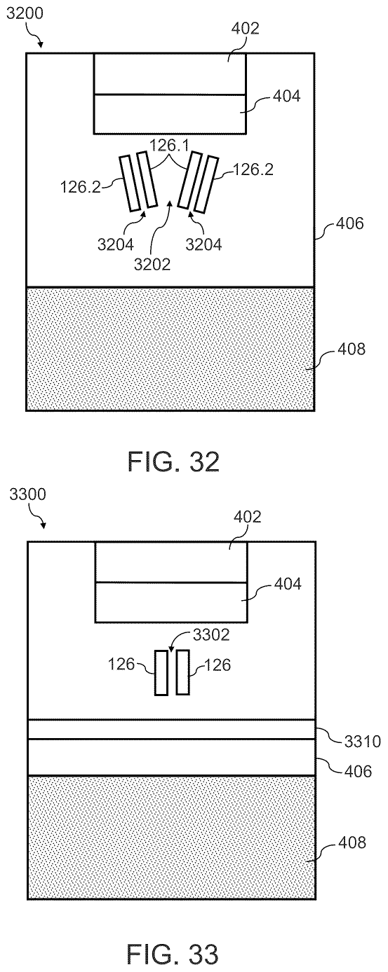

Like the crystal growth systems of FIGS. 4A-29, the crystal growth system 3200 of FIG. 32 includes many similar components. The crystal growth system 3200 includes the baffle 126, the seed holder 402, the seed crystal 404, the crucible 406, and the source material 408. The baffle 126 includes a plurality of parallel tubular structures 126.1 and 126.2. The baffle 126 includes a first aperture 3202 through a first tubular structure 126.1. The baffle 126 includes a second aperture 3204 between the first tubular structure 126.1 and the second tubular structure 126.2. The first tubular structure 126.1 and the second tubular structure 126.2 may be arranged concentrically with one another. The sidewall of both the first tubular structure 126.1 and the second tubular structure 126.2 may be non-perpendicular to the growth surface of the seed crystal 404. For instance, the sidewalls may be angled toward a peripheral portion of the seed crystal 404.

The baffle 126 may be positioned in any spatial relation to the seed crystal 404, such as overlapping one or more peripheral portions of the seed crystal, overlapping one or more sidewall portions of the seed crystal, or in closer proximity to the source material 408 relative to the proximity of the baffle 126 to the seed crystal 404, and so forth. In some examples, the baffle 126 may be coupled to a side wall of the crucible 406.

Like the crystal growth systems of FIGS. 4A-32, the crystal growth system 3300 of FIG. 33 includes many similar components. The crystal growth system 3300 includes the baffle 126, the seed holder 402, the seed crystal 404, the crucible 406, and the source material 408. The baffle 126 includes a tubular baffle structure 126 having a sidewall 3302 that forms a channel-like aperture 3304. The sidewall 3302 of the baffle 126 may form a tubular structure (e.g., cylindrical tube). The sidewall 3302 may be generally perpendicular to a growth surface of the seed crystal 404. Further, the baffle 126 is depicted as overlapping a central portion of the seed crystal 404. The baffle 126 may be positioned in any spatial relation to the seed crystal 404, such as overlapping one or more peripheral portions of the seed crystal, overlapping one or more sidewall portions of the seed crystal, or in closer proximity to the source material 408 relative to the proximity of the baffle 126 to the seed crystal 404, and so forth. In some examples, the baffle 126 may be coupled to a side wall of the crucible 406.

As shown in FIG. 33, the crystal growth system 330 may include a second baffle 3310 or baffle plate. The second baffle 3310 can take the form of any of the baffles described herein. In some embodiments, the second baffle 3310 does not include apertures and is graphite (e.g., porous graphite). In some examples, the second baffle 3310 may be a secondary source material for the crystal growth system 3300. For instance, the second baffle 3310 may include a silicon carbide source material and/or a carbon source material (e.g., at least partially uncoated graphite with an exposed graphite surface).

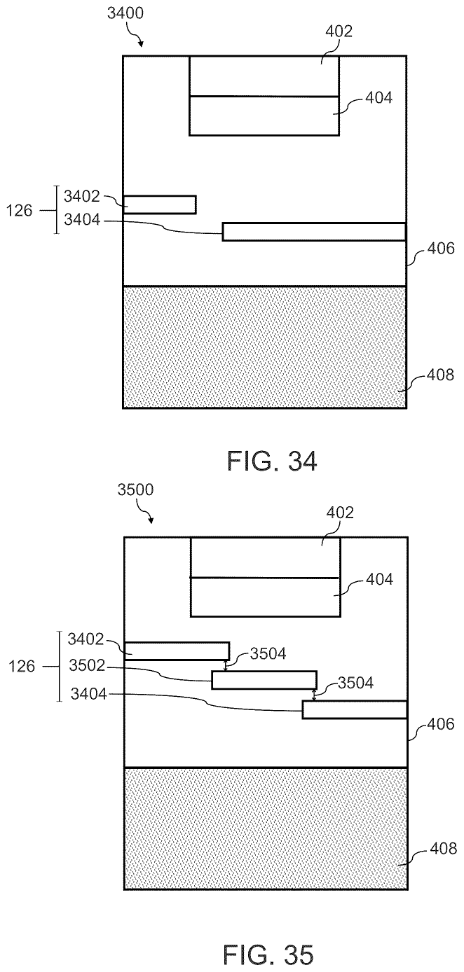

Like the crystal growth systems of FIGS. 4A-33, the crystal growth system 3400 of FIG. 34 includes many similar components. The crystal growth system 3400 includes the baffle 126, the seed holder 402, the seed crystal 404, the crucible 406, and the source material 408. The baffle 126 includes a first divider 3402 and a second divider 3404. The first divider 3402 may extend into the crystal growth chamber from a first wall of the crucible 406. The second divider 3404 may extend in the crystal growth chamber from a wall of the crucible 406 opposite the first wall, at a different vertical position than the first divider 3402 such that the first divider 3402 and the second divider 3404 do not overlap. The lack of overlap between the first divider 3402 and the second divider 3404 may allow a liner transport path of source vapor from the source material 408 to the seed crystal 404.

Like the crystal growth systems of FIGS. 4A-34, the crystal growth system 3500 of FIG. 35 includes many similar components. The crystal growth system 3500 includes the baffle 126, the seed holder 402, the seed crystal 404, the crucible 406, and the source material 408. The baffle 126 includes a first divider 3402, a second divider 3404, and a third divider 3502. The first divider 3402 may extend into the crystal growth chamber from a first wall of the crucible 406. The second divider 3404 may extend in the crucible 406 from a wall of the crucible 406 opposite the first wall, at a different vertical position than the first divider, such that the first divider 3402 and the second divider 3404 are about the same length. The third divider 3502 may be positioned between the first divider 3402 and the second divider 3404 such that a length of the third divider 3502, at least partially, overlaps with a length of the first divider 3402 and the second divider 3404. A vertical gap 3504 may be provided between the first divider 3402 and the third divider 3502, such that source vapor may be transported in a non-linear path from the source material 408 to the seed crystal 404. The vertical gap 3504 of the first divider 3402, the second divider 3404, and the third divider 3502 may be configured such that the vertical gap 3504 is about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm.

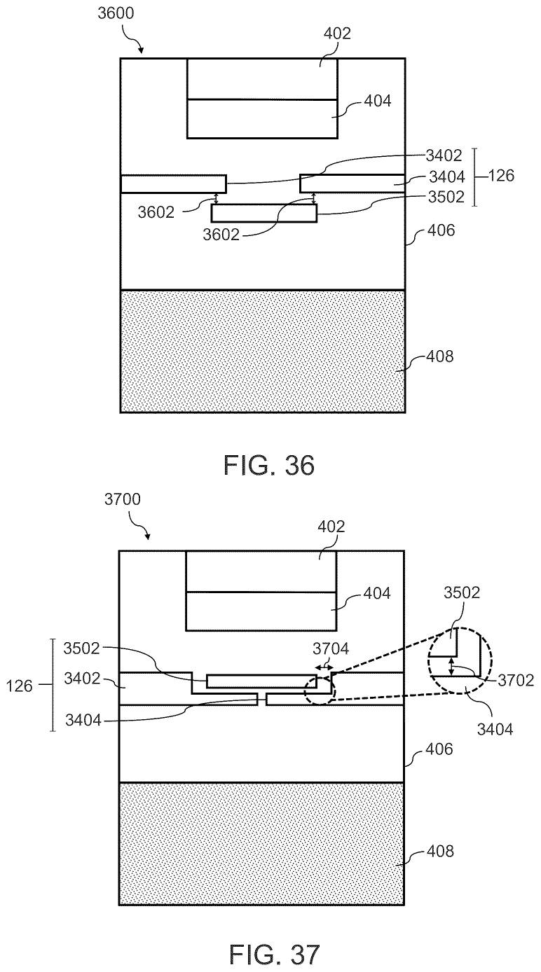

Like the crystal growth systems of FIGS. 4A-35, the crystal growth system 3600 of FIG. 36 includes many similar components. The crystal growth system 3600 includes the baffle 126, the seed holder 402, the seed crystal 404, the crucible 406, and the source material 408. The baffle 126 includes a first divider 3402, a second divider 3404, and a third divider 3502. The first divider 3402 may extend into the crystal growth chamber from a first wall of the crucible 406. The second divider 3404 may extend in the crucible 406 from a wall of the crucible 406 opposite the first wall, at the same vertical position as the first divider 3402, such that the first divider 3402 and the second divider 3404 are about the same length. The third divider 3502 may be positioned between the first divider 3402 and the second divider 3404 at a different vertical position than the first divider 3402 and the second divider 3502, such that a length of the third divider 3502, at least partially, overlaps with a length of the first divider 3402 and the second divider 3404. A vertical gap 3602 may be provided between the first divider 3402 and the third divider 3502, such that source vapor may be transported in a non-linear path from the source material 408 to the seed crystal 404. The vertical gap 3602 may be provided between the third divider 3502 and the second divider 3404, such that source vapor may be transported in a non-linear path from the source material 408 to the seed crystal 404. The vertical gap 3602 of the first divider 3402, the second divider 3404, and the third divider 3502 may be configured such that the vertical gap 3602 is less about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm.

Like the crystal growth systems of FIGS. 4A-36, the crystal growth system 3700 of FIG. 37 includes many similar components. The crystal growth system 3700 includes the baffle 126, the seed holder 402, the seed crystal 404, the crucible 406, and the source material 408. In some examples, the baffle 126 may be coupled to a side wall of the crucible 406. In some examples, the baffle 126 may not fully extend between the inner walls of the crucible 406.

The baffle 126 may include the first divider 3402, which may extend into the crystal growth chamber from a first wall of the crucible 406. The first divider 3402 may have an irregular shape such that a lower portion of the first divider 3402 extends into the crystal growth chamber further than an upper portion of the first divider 3402. The baffle 126 may include the second divider 3404, which may extend into the crystal growth chamber from a wall of the crucible 406 opposite to the first divider 3402 at the same vertical position. The second divider 3404 may have an irregular shape such that a lower portion of the second divider 3404 extends into the crystal growth chamber further than an upper portion of the second divider 3404. The third divider 3502 may be positioned between the first divider 3402 and the second divider 3404 such that a length of the third divider 3502, at least partially, overlaps with a length of the lower portion first divider 3402 and a lower portion of the second divider 3404. A vertical gap 3702 may be provided between the first divider 3402 and the third divider 3502, such that source vapor may be transported in a non-linear path from the source material 408 to the seed crystal 404. A vertical gap 3702 may be provided between the second divider 3404 and the third divider 3502, such that source vapor may be transported in a non-linear path from the source material 408 to the seed crystal 404. A horizontal gap 3704 may be provided such that source vapor may be transported in a non-linear path from the source material 408 to the seed crystal 404. The vertical gap 3702 or the horizontal gap 3704 of the first divider 3402, the second divider 3404, and the third divider 3502 may be configured such that the vertical gap 3702 or the horizontal gap 3702 is about 20% or less than a width of the crystal growth chamber, such as about 15% or less, such as about 10% or less, such as about 5% or less, such as about 0.5 mm to about 10 mm, such as 3 mm to about 8 mm, such as 4 mm to about 6 mm.

In some embodiments, the third divider 3502 may be a secondary source material for the crystal growth system 3700. For instance, the third divider 3502 may include a silicon carbide source material and/or a carbon source material (e.g., at least partially uncoated graphite with an exposed graphite surface) for the crystal growth system 3700.

In some embodiments, the baffle 126 may be a composite shaped structure. A composite shaped structure. As used herein, “composite shape” and “composite shaped” refer to any three-dimensional object or component that deviates from a regular cylindrical shape, or a composite solid structure containing multiple shaped solids which may have simple or complex shapes. Deviations from a cylindrical shape include forms with regular or irregular geometries that do not conform to the typical circular or elliptical cross-section of a cylinder. Such structures may exhibit various shapes, including but not limited to structures with polygonal cross-sections; irregularly curved structures; and shapes with holes, voids, surface variations, or combinations thereof. The term also includes shapes containing multiple interconnected or distinct substructures. The substructures may themselves be composite shaped or may be cylindrically shaped. The term encompasses a wide range of geometric configurations and excludes objects that maintain a uniform cylindrical profile throughout their entire volume.

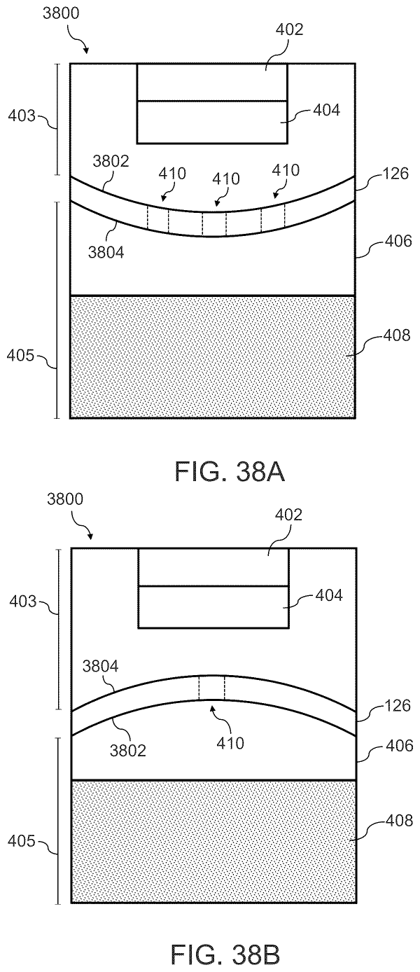

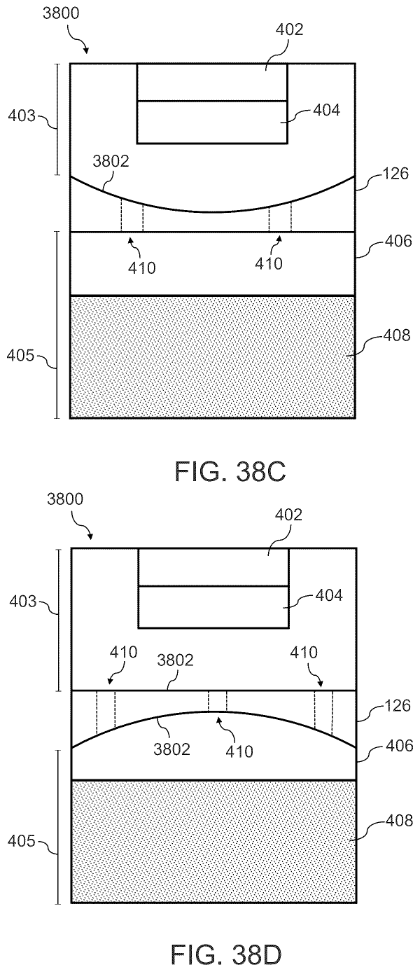

Like the crystal growth systems of FIGS. 4A-37, the crystal growth system 3800 of FIGS. 38A and 38B includes many similar components. The crystal growth system 3800 includes the baffle 126, the seed holder 402, the seed crystal 404, the crucible 406, and the source material 408. In some examples, the baffle 126 may extend between the inner walls of the crucible 406, such that the crucible 406 is bisected or divided into the upper portion 403 and the lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

The baffle 126 may include a concave surface 3802 and a convex surface 3804. In some examples, the concave surface 3802 of the baffle 126 may be closest in proximity to the seed crystal 404, and the convex surface 3804 may be closest in proximity to the source material 408 as depicted in FIG. 38A. In some examples, the concave surface 3802 of the baffle 126 may be closest in proximity to the source material 408, and the convex surface 3804 may be closest in proximity to the seed crystal 404 as depicted in FIG. 38B. In some examples, the baffle 126 may not include any apertures, and may rely on transport of source vapor through the material of the baffle 126 to transport source vapor from the source material 408 to the seed crystal 404. In some examples, the baffle 126 may include one or more apertures 410, represented by the dashed lines.

As depicted in FIG. 38C the baffle 126 may include the first surface that is the concave surface 3802. The second surface (e.g., the surface that opposes the concave surface 3802) may be a flat surface. In some examples, the baffle 126 with the first surface that is the concave surface 3804 may be positioned such that the concave surface 3802 is closest in proximity to the seed crystal 404. As depicted in FIG. 38D, the baffle 126 may include the concave surface 3802. The baffle 126 may be positioned such that the concave surface 3802 is closest in proximity to the source material 408.

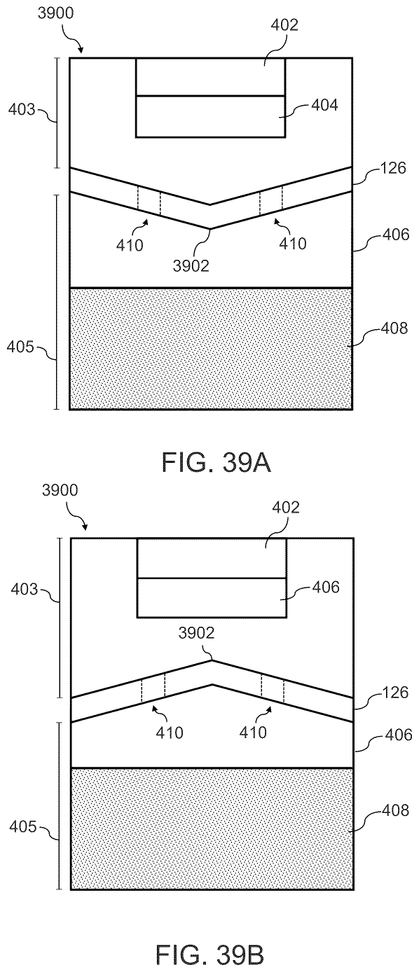

Like the crystal growth systems of FIGS. 4A-38B, the crystal growth system 3900 of FIGS. 39A and 39B includes many similar components. The crystal growth system 3800 includes the baffle 126, the seed holder 402, the seed crystal 404, the crucible 406, and the source material 408. In some embodiments, the baffle 126 may extend between the inner walls of the crucible 406, such that the crucible 406 is bisected or divided into the upper portion 403 and the lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

The baffle 126 may include a chevron or v-shape with linear portions intersecting in a peak 3902. In some examples, the peak 3902 of the baffle 126 may be closest in proximity to the source material 408, as depicted in FIG. 39A. In some examples, the peak 3902 may be closest in proximity to the seed crystal 404, as depicted in FIG. 39B. In some examples, the baffle 126 may not include any apertures, and may provide for transport of source vapor through the material of the baffle 126 to transport source vapor from the source material 408 to the seed crystal 404. In some examples, the baffle 126 may include one or more apertures 410, represented by the dashed lines.

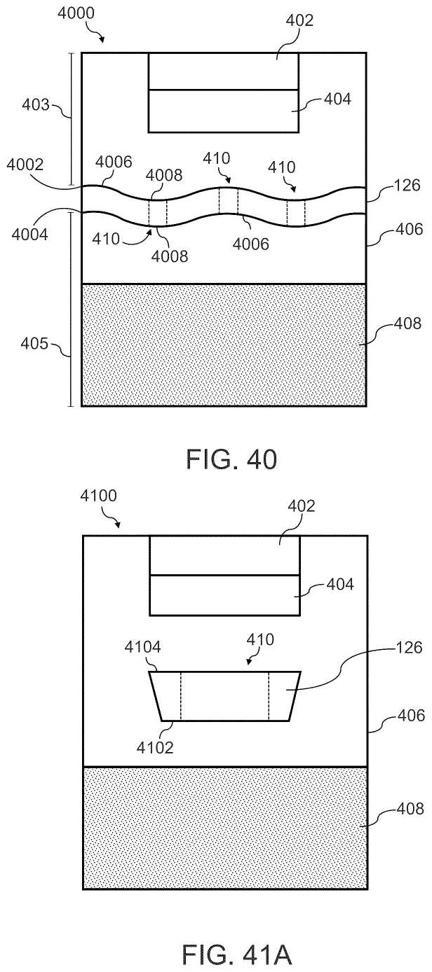

Like the crystal growth systems of FIGS. 4A-39B, the crystal growth system 4000 of FIG. 40 includes many similar components. The crystal growth system 4000 includes the baffle 126, the seed holder 402, the seed crystal 404, the crucible 406, and the source material 408. In some embodiments, the baffle 126 may extend between the inner walls of the crucible 406, such that the crucible 406 is bisected or divided into the upper portion 403 and the lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

The baffle 126 may have a wave-like shape, with an upper surface 4002 that is closest in proximity to the seed crystal 404 and a lower surface 4004 that is closest in proximity to the source material 408. The upper surface may have a peak 4006 (e.g., a relative maxima) and a trough 4008 (e.g., a relative minima). Likewise, the lower surface may have the peak 4006 (e.g., a relative maxima) and the trough 4008 (e.g., a relative minima). In some examples, the baffle 126 may not include any apertures, and may provide for transport of source vapor through the material of the baffle 126 to transport source vapor from the source material 408 to the seed crystal 404. In some examples, the baffle 126 may include one or more apertures that assist with source vapor transport from the source material 408 to the seed crystal 404. In examples including the one or more apertures, the apertures may include one or more holes, rings, or other shaped apertures of any size as provided herein.

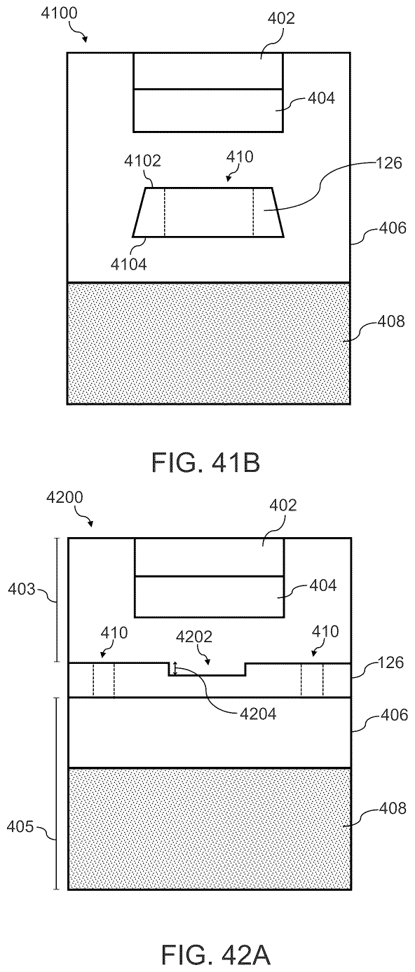

Like the crystal growth systems of FIGS. 4A-40, the crystal growth system 4100 of FIGS. 41A and 41B includes many similar components. The crystal growth system 4100 includes the baffle 126, the seed holder 402, the seed crystal 404, the crucible 406, and the source material 408. In some examples, the baffle 126 may be coupled to a side wall of the crucible 406. In some examples, the baffle 126 may not fully extend between the inner walls of the crucible 406. Further, the baffle 126 is depicted as being in a central portion of the crystal growth system 4100. The baffle 126 may be positioned in any spatial relation to the seed crystal 404, such as at or near one or more peripheral portions of the seed crystal, at or near one or more sidewall portions of the seed crystal, or in closer proximity to the source material 408 relative to the proximity of the baffle 126 to the seed crystal 404, etc.

The baffle 126 may have a surface with a longer dimension 4104 and a surface with a short dimension 4102. As depicted in FIG. 41A, the surface with the long dimension 4104 may be closest in proximity to the seed crystal 404, while the surface with the short dimension 4102 may be closest to the source material 408. As depicted in FIG. 41B, the surface with the long dimension 4104 may be closest in proximity to the source material 408, while the surface with the short dimension 4102 may be closest to the seed crystal 404. The baffle 126 of FIGS. 41A and 41B is depicted as having a trapezoid cross-section, the baffle may take another shape, such as a quadrilateral (e.g., a parallelogram, a rhombus, diamond, etc.), a triangular shape, an oval, an ellipse, etc. In some examples, the baffle 126 may not include any apertures, and may provide for transport of source vapor through the material of the baffle 126 to transport source vapor from the source material 408 to the seed crystal 404 (e.g., porous graphite). In some embodiments, an aperture may be defined through the baffle 126 of FIGS. 41A and 41B such that the baffle 126 is a tubular structure.

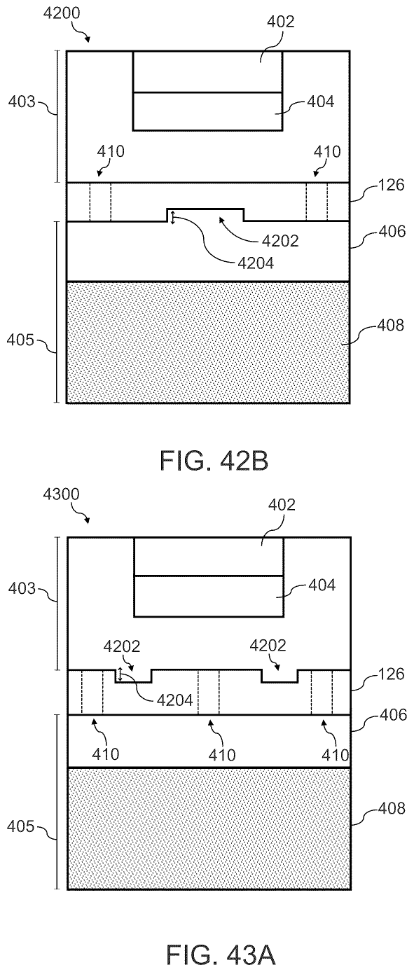

Like the crystal growth systems of FIGS. 4A-41B, the crystal growth system 4200 of FIGS. 42A and 42B includes many similar components. The crystal growth system 4200 includes the baffle 126, the seed holder 402, the seed crystal 404, the crucible 406, and the source material 408. In some embodiments, the baffle 126 may extend between the inner walls of the crucible 406, such that the crucible 406 is bisected or divided into the upper portion 403 and the lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

The baffle 126 may include a recessed cavity 4202. The recessed cavity 4202 may have a vertical dimension 4204 that does not exceed the thickness of the baffle 126. That is, the recessed cavity 4202 extends partially into the thickness of the baffle 126 without extending through the thickness of the baffle 126. As depicted in FIG. 42A, the recessed cavity 4202 may be on a surface of the baffle 126 closest in proximity to the seed crystal 404. As depicted in FIG. 42B, the recessed cavity 4202 may be on a surface of the baffle 126 closest in proximity to the source material 408. The recessed cavity 4202 is depicted as being centered under a central portion of the seed crystal 404 for purposes of discussion only, the recessed cavity 4202 may be positioned anywhere on the surface of the baffle 126, such as under a peripheral portion of the seed crystal 404 or under a sidewall portion of the seed crystal 404.

If the baffle 126 is serving as a secondary source, the baffle 126 may be etched such that the recessed cavity 4202 becomes an aperture extending through the thickness of the baffle during a crystal growth process. This may alter crystal growth conditions (e.g., a thermal gradient, diffusion factors, kinetics of source vapor, a chemical environment, etc.) during a crystal growth process to positively contribute to crystal growth. Additionally, such recessed cavity 4202 may serve to break up any undesired eddies of vapor to create a desired vapor pressure at growth crystal or increased vapor transport if used as secondary source and/or to have a desired effect on thermal gradients along a crystal surface. There can be any suitable arrangement of one or more recessed cavities in the baffle 126 without deviating from the scope of the present disclosure.

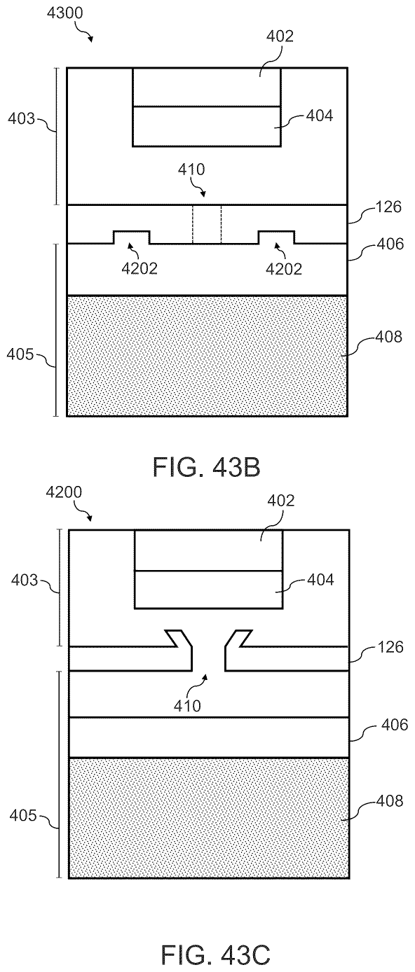

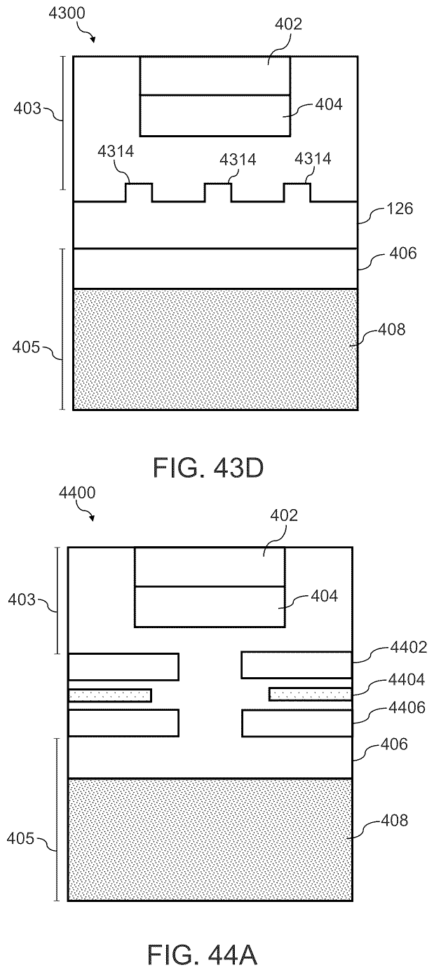

For instance, as depicted in FIGS. 43A and 43B, the baffle 126 may include a plurality of recessed cavities 4202. As depicted in FIG. 43A, the plurality of recessed cavities 4202 may be on a surface of the baffle 126 closest in proximity to the seed crystal 404. As depicted in FIG. 43B, the plurality of recessed cavities 4202 may be on a surface of the baffle 126 closest in proximity to the source material 408. The plurality of recessed cavities 4202 are depicted as being under a peripheral portion of the seed crystal 404 for purposes of discussion only, the plurality of recessed cavities 4202 may be positioned anywhere on the surface of the baffle 126, such as under a peripheral portion of the seed crystal 404 or under a sidewall portion of the seed crystal 404. The baffle 126 is depicted as including two recessed cavities 4202 in the plurality of recessed cavities 4202 for purposes of discussion only, the baffle 126 may include any number of recessed cavities 4202.

In some embodiments, as depicted in FIG. 43C and FIG. 43D, the baffle 126 may include one or more protrusions that extend from a surface of the baffle 126. For instance, in FIG. 43C, protrusion 4312 extends around an aperture 410. The protrusion 4312 extends in a non-perpendicular direction relative to the growth surface of the seed crystal 404. The protrusion 4312 can have any length, shape, and/or configuration to modify vapor transport or radiative heat transfer to the seed crystal 404. The protrusion 4312 may be used to direct vapor transport uniformly across the growth surface of the seed crystal 404. In some embodiment, the baffle 126 may include one or more protrusions to provide vapor transport more toward or central portion of the seed crystal 404 relative to a peripheral portion of the seed crystal 404 and vice versa.

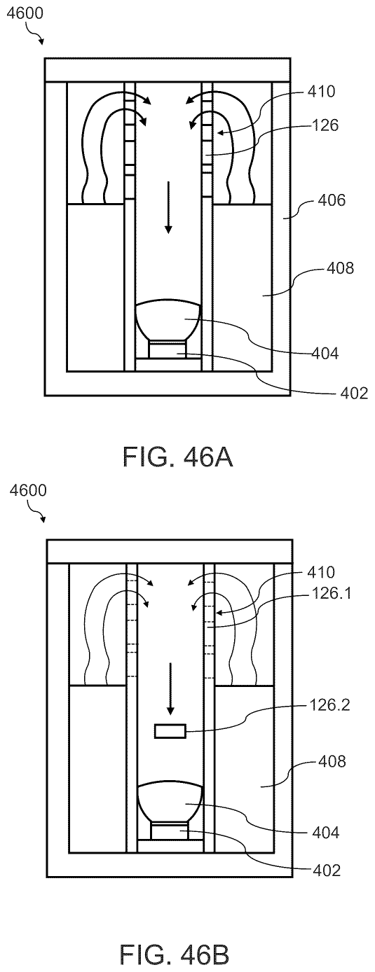

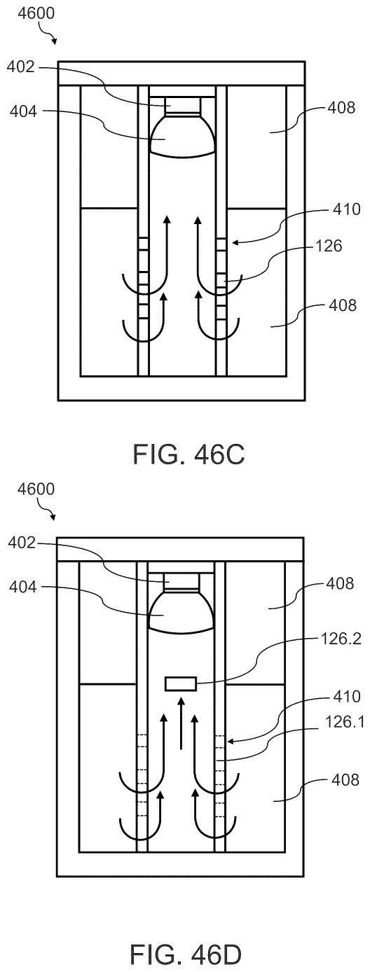

The protrusion 4312 may extend in any direction relative to the bulk material surface of the baffle 126 or the growth surface of the seed crystal 404. The baffle 126 may include any number of protrusions without deviating from the scope of the present disclosure. For instance, as illustrated in FIG. 43D, the baffle 126 includes three protrusions 4314 that extend in a perpendicular direction towards the seed crystal 404. Any of the protrusions provided herein could similarly extend toward the source material 408 without deviating from the scope of the present disclosure. The baffle 126 of FIGS. 46C and 46D may include other features, such as apertures, recessed cavities, slits, pores, etc. in any combination without deviating from the scope of the present disclosure.

Any of the baffle structures described herein may act as a secondary source material for a crystal growth process. For instance, in some embodiments, one or more portions of the baffle structure may be uncoated and include exposed graphite that acts as a carbon source for the crystal growth process. In some embodiments, one or more portions of the baffle structure may include a silicon carbide source material (e.g., silicon carbide powder, solid silicon carbide source, etc.).

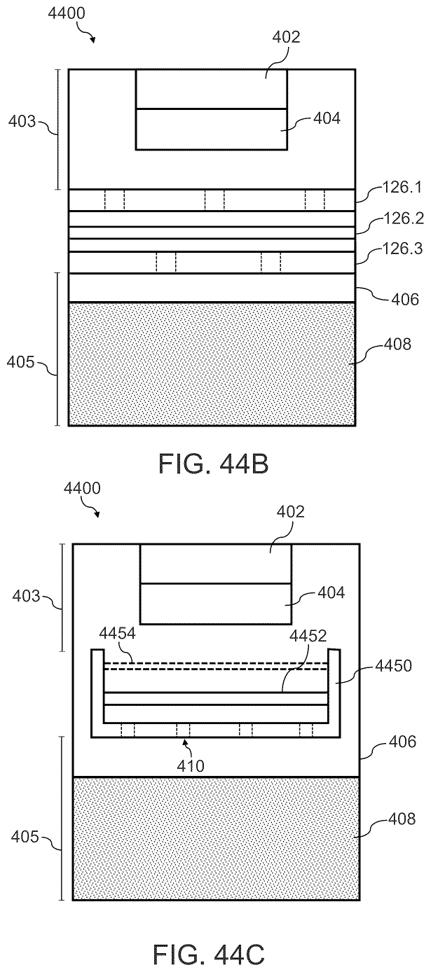

Like the crystal growth systems of FIGS. 4A-43D, the crystal growth system 4400 of FIG. 44A includes many similar components. The crystal growth system 4400 includes the baffle 126, the seed holder 402, the seed crystal 404, the crucible 406, and the source material 408. In some embodiments, the baffle 126 may extend between the inner walls of the crucible 406, such that the crucible 406 is bisected or divided into the upper portion 403 and the lower portion 405 by the baffle 126. The upper portion 403 and the lower portion 405 may have the same or different volumes. In some examples, the baffle 126 may be coupled to a side wall of the crucible 406. In some examples, the baffle 126 may not fully extend between the inner walls of the crucible 406.

In the example of FIG. 44A, the baffle structure includes multiple baffle plates, such as a first baffle plate 4402, a second baffle plate 4404, and a third baffle plate 4406. The first baffle plate 4402, the second baffle plate 4404, and the third baffle plate 4406 may be configured as any of the baffles provided herein. In some embodiments, the first baffle plate 4402 and the third baffle plate 4406 may be the same material (e.g., graphite).

The second baffle plate 4404 may be a secondary source material for the crystal growth process. For instance, in some embodiments, the second baffle plate 4404 may be an uncoated graphite structure that serves as a carbon source for silicon carbide species in the crystal growth process. In some embodiments, the second baffle plate 4404 may be a silicon carbide vapor source (e.g., may include silicon carbide powder or may be a solid silicon carbide source). The second baffle plate 4404 may be positioned between the first baffle plate 4402 and the third baffle plate 4406.

In the example of FIG. 44B, the baffle 126 includes a plurality of baffle structures, such as a first baffle plate 126.1, a second baffle plate 126.2, and a third baffle plate 126.3. Any of the baffle plates 126.1, 126.2, and 126.3 may be configured according to any of the baffles disclosed herein. In some embodiments, each of the baffle plates 126.1, 126.2, and 126.3 may serve one or more different functions. For instance, the first baffle plate 126.1 may serve to control vapor transport and act as a second source. The second baffle plate 126.2 may control radiative heat transfer and vapor transport. The third baffle plate 126.3 may act as a filter to reduce inclusions in the seed crystal 404. Other suitable combinations of functions/structures may be used without deviating from the scope of the present disclosure.

In the example of FIG. 44C, the baffle 126 includes one or more baffle structure arranged within a cavity defined by a different baffle structure. More particularly, the baffle 126 includes a tubular baffle 4450 that may or may not include apertures. Within a cavity defined by the tubular baffle 4450, the baffle may include one or more additional baffle structures, such as baffle structure 4452 and baffle structure 4454 and other additional baffle structures. The baffle structure 4452 and the baffle structure 4454 may be any of the baffles disclosed herein.

The tubular baffle 4450 may have other suitable arrangements without deviating from the scope of the present disclosure. For instance, the cavity could be proximate the seed crystal 404 as shown in FIG. 44C or proximate the source material. The baffle could have a plurality of different cavities for holding baffle structures. The cavities can be arranged in any pattern or on any surface of the baffle without deviating from the scope of the present disclosure. The walls of the baffle defining the cavity can extend in any direction, such as a generally perpendicular direction to the growth surface of the seed crystal 404 or a non-perpendicular direction to the growth surface of the seed crystal 404.

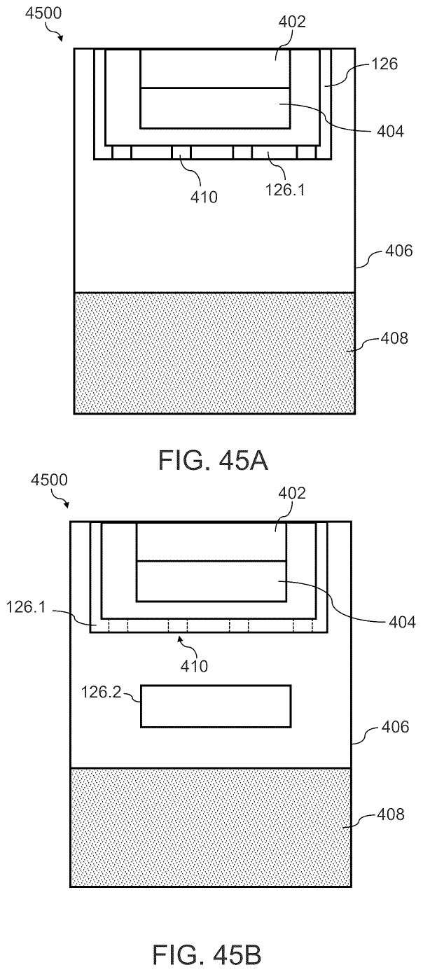

Aspects of the present disclosure may be used with various types of crystal growth systems without deviating from the scope of the present disclosure. For instance, FIGS. 45A-48B depict the use of baffles according to examples of the present disclosure in a wide variety of crystal growth system configurations. In any of the examples below, the baffle or baffle elements may be located on the source material, may be spaced apart from the source material and/or the seed material or may be proximate the seed material. In some embodiments, the system may include any number of baffles or baffle elements without deviating from the scope of the present disclosure. In some embodiments, the source material may have a baffle or baffle element incorporated therein.

FIGS. 45A and 45B depict example crystal growth systems 4500 according to example embodiments of the present disclosure. In FIG. 45A, the crystal growth system 4500 includes the baffle 126.1, the seed holder 402, the seed crystal 404, the crucible 406, and the source material 408. The baffle 126 may be positioned such that the baffle 126.1 extends around at least three sides of the seed crystal 404, with the longest dimension located below the seed crystal 404. The baffle 126 may be referred to as a shell structure as it provides a shell around the seed crystal 404. The baffle 126 may be graphite, such as porous graphite. The baffle 126.1 may include one or more apertures 410 that assist in the transport of source vapor from the source material 408 to the seed crystal 404.

In some examples, such as the example depicted in FIG. 45B, the baffle 126.1 may or may not include any apertures 410. The baffle 126.1 may be porous graphite and may have a porosity of greater than about 70%. The baffle 126.1 may be positioned such that the baffle 126.1 extends around at least three sides of the seed crystal 404, with the longest dimension located below the seed crystal 404. The system 4800 may include one or more second baffles 126.2. The one or more second baffles 126.2 may include any of the baffles contemplated by the present disclosure, such as any of the baffles depicted in FIGS. 4A-44C. The one or more second baffles may be arranged in the vapor transport path from the source material 408 to the seed crystal 404.

FIGS. 46A through 46D depict example crystal growth systems 4600 according to example embodiments of the present disclosure. In FIG. 46A, the crystal growth system 4600 includes a baffle 126.1, a seed holder 402, a seed crystal 404, a crucible 406, and the source material 408. The baffle 126.1 may include a tubular baffle structure. The seed crystal 404 may be within the tubular baffle 126.1. The baffle 126.1 may be graphite, such as porous graphite. The baffle 126.1 may include one or more apertures 410 that assist in the transport of source vapor from the source material 408 to the seed crystal 404.

FIG. 46B depicts a crystal growth system similar to that of FIG. 46A. In FIG. 46B, the tubular baffle 126.1 may or may not include any apertures 410. The system 4600 may further include one or more second baffles 126.2. The one or more second baffles 126.2 may be arranged in the vapor transport path between the source material 408 and the seed crystal 404. The one or more second baffles 126.2 may include any of the baffles contemplated by the present disclosure, such as any of the baffles depicted in FIGS. 4A-44C. Source vapor may be transported through the baffles 126.1 and 126.2. The baffle 126.1 and/or the baffle(s) 126.2 may reduce graphite inclusions or other impurities resulting from gravitational forces pulling impurities toward the seed crystal 404.

FIG. 46C depicts a crystal growth system similar to that of FIG. 46A. In FIG. 46C, the crystal growth system 4600 includes the seed crystal 404 at the top of the crucible 406. Similar to FIG. 46A, the baffle 126.1 may include a tubular baffle structure. The seed crystal 404 may be within the tubular baffle 126.1. The baffle 126.1 may be graphite, such as porous graphite. The baffle 126.1 may include one or more apertures 410 that assist in the transport of source vapor from the source material 408 to the seed crystal 404.

FIG. 46D depicts a crystal growth system 4600 similar to that of FIG. 46B. In FIG. 46D, the crystal growth system includes the seed crystal 404 at the top of the crucible 406. Similar to the crystal growth system 4600 of FIG. 46B, the tubular baffle 126.1 may or may not include apertures 410. The system 4600 may further include one or more second baffles 126.2. The one or more second baffles 126.2 may be arranged in the vapor transport path between the source material 408 and the seed crystal 404. The one or more second baffles 126.2 may include any of the baffles contemplated by the present disclosure, such as any of the baffles depicted in FIGS. 4A-44C. Source vapor may be transported through the baffles 126.1 and 126.2.

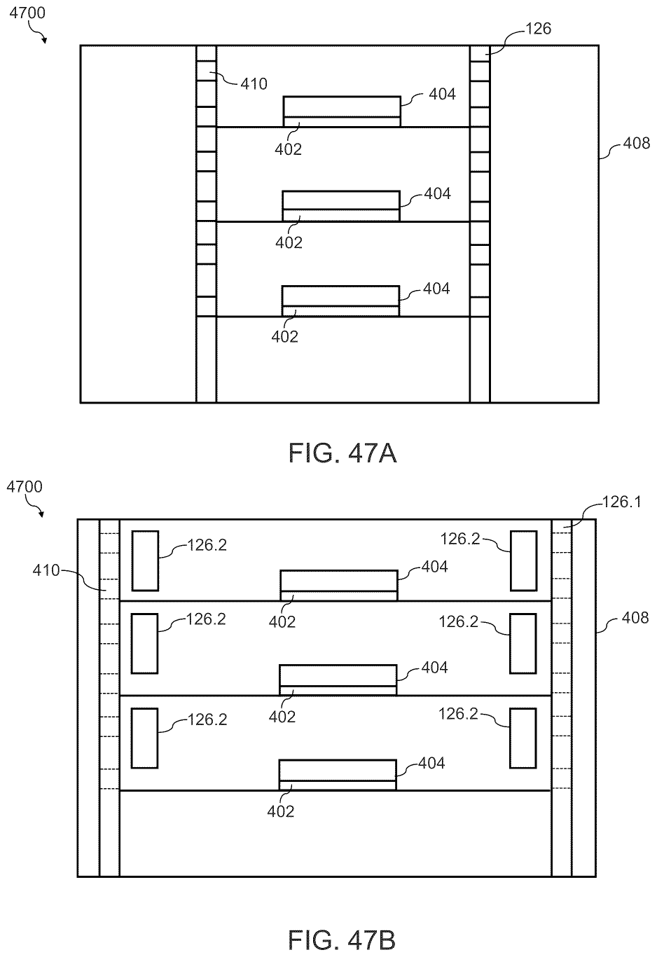

FIGS. 47A and 47B depict example crystal growth systems 4700 that may be used to grow a plurality of silicon carbide boules according to example embodiments of the present disclosure. In FIG. 47A, the crystal growth system 4700 includes a plurality of seed holders 402 and seed crystals 404 arranged in different crystal growth chambers. A baffle 126.1 may separate the seed crystals 404 from a source material 408. As depicted in FIG. 47A, the baffle 126.1 may include one or more apertures 410 to assist with vapor transport from the source material 408 to the seed crystals 404. The one or more apertures 410 may have a shape and/or arrangement as any of the apertures provided herein.

In some embodiments, as depicted in FIG. 47B, the crystal growth system 4700 may include one or more second baffles 126.2 in each chamber. The second baffle(s) 126.2 may be arranged in the vapor transport path between the source material 408 and the seed crystal 404 in each chamber. Each of the one or more second baffles 126.2 may include any of the baffles contemplated by the present disclosure, such as any of the baffles depicted in FIGS. 4A-44C. Source vapor may be transported through the baffles 126.1 and 126.2.

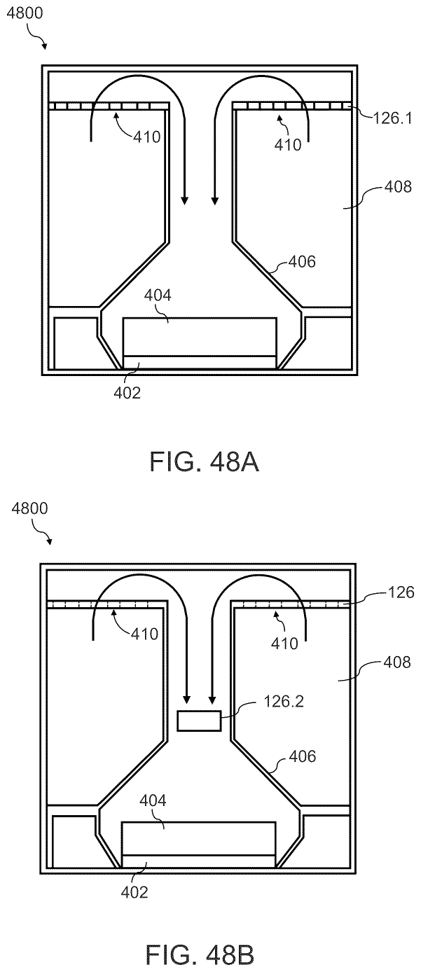

FIGS. 48A and 48B depict example crystal growth systems 4800 according to example embodiments of the present disclosure. In FIG. 48A, the crystal growth system 4800 includes a seed holder 402 and a seed crystal 404 arranged within a crucible 406. The crucible 406 may have one or more angled sidewalls. The crystal growth system 4800 includes a source material 408. The baffle 126.1 may be on top of the source material 408 and may separate the source material 408 from the reaction chamber defined by the crucible 406. As depicted in FIG. 48A, the baffle 126.1 may include one or more apertures 410 to assist with vapor transport from the source material 408 to the seed crystal 404. The one or more apertures 410 may have a shape and/or arrangement as any of the apertures provided herein.

FIG. 48B depicts a crystal growth system similar to that of FIG. 48A. In FIG. 48B, the baffle structure 126.1 may or may not include any apertures 410. The system 4800 may further include a second baffle 126.2. The second baffle may be in the transport path between the source material 408 and the seed crystal 404. The second baffle 126.2 may include any of the baffles contemplated by the present disclosure, such as any of the baffles depicted in FIGS. 4A-44C. Source vapor may be transported through the baffles 126.1 and 126.2 to the seed crystal 404. The baffle 126.1 and/or the baffle 126.2 may serve to reduce graphite inclusions or other impurities resulting from gravitational forces pulling impurities toward the seed crystal 404.

Example aspects of the present disclosure are set forth below. Any of the below features or examples may be used in combination with any of the embodiments or features provided in the present disclosure.

In one example, aspects of the present disclosure are directed toward a crystal growth system for growing crystalline material, the crystalline material including silicon carbide. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes one or more baffles within the crystal growth chamber and spaced apart from the source material. The one or more baffles include one or more apertures defined through the one or more baffles. The baffle includes a long dimension that is non-perpendicular to the growth surface of the seed crystal.

In some examples, each of the one or more apertures has a width that is less than about 20% of a width of the crystal growth chamber.

In some examples, each of the one or more apertures provides a path through the baffle for transport of vapor from the source material to the seed crystal without having significant crystal growth formation in the aperture.

In some examples, each of the one or more apertures provides a thermal gradient in a direction along a thickness of the aperture. In some examples, a silicon carbide vapor is transported through a material of the baffle at a first rate and is transported through the one or more apertures at a second rate. The first rate is different than the second rate.

In some examples, the one or more apertures comprise a plurality of holes defined through the baffle.

In some examples, the one or more apertures includes an annular aperture defined through the baffle.

In some examples, a vapor transport direction through the one or more apertures is in a non-perpendicular direction relative to the growth surface of the seed crystal.

In some examples, the one or more apertures are arranged in the baffle to provide for asymmetric crystal growth on the seed crystal.

In some examples, the one or more apertures include a first aperture and a second aperture, wherein a width of the first aperture is different from a width of the second aperture.

In some examples, the one or more apertures include a first plurality of apertures and a second plurality of apertures, wherein a density of the first plurality of apertures in the baffle is different from a density of the second plurality of apertures in the baffle.

In some examples, the first plurality of apertures are in a central portion of the baffle and the second plurality of apertures are in a peripheral portion of the baffle.

In some examples, the baffle includes a plurality of dividers arranged in a non-perpendicular direction relative to the growth surface of the seed crystal.

In some examples, the one or more apertures are arranged to transport vapor in a vapor transport direction that is more towards a central portion of the seed crystal relative to a peripheral portion of the seed crystal.

In some examples, the one or more apertures are arranged to direct vapor in a vapor transport direction that is more towards a peripheral portion of the seed crystal relative to a central portion of the seed crystal.

In some examples, a thickness of the baffle is in a range of about 0.5 mm to about 25 mm.

In some examples, a width of the baffle is at least 10 times greater than the thickness.

In some examples, the baffle includes a plurality of baffle plates.

In some examples, the baffle includes a first baffle plate having the one or more apertures and a second baffle plate with no apertures.

In some examples, the baffle includes a first baffle plate including a first aperture and a second baffle plate including a second aperture.

In some examples, the first aperture is aligned with the second aperture.

In some examples, the first aperture is not aligned with the second aperture.

In some examples, the first aperture has a different width relative to the second aperture.

In some examples, the baffle includes a first baffle plate including a first material and a second baffle plate including a second material.

In some examples, the first baffle plate includes graphite and the second baffle plate includes a secondary source material.

In some examples, the baffle includes a third baffle plate, wherein the third baffle plate includes the first material.

In some examples, the second baffle plate is arranged between the first baffle plate and the third baffle plate.

In some examples, the baffle includes graphite.

In some examples, the baffle includes a coating on the graphite.

In some examples, the coating is a pyrolytic coating.

In some examples, the coating includes tantalum carbide.

In some examples, the baffle has a porosity in a range of about 70% to about 97%.

In some examples, the baffle includes a tubular structure.

In some examples, the tubular structure includes a sidewall that is non-perpendicular relative to the growth surface.

In some examples, the baffle is spaced apart from the seed holder and is not coupled to the seed holder.

In some examples, the baffle is coupled to a side wall of the crucible.

In some examples, a width of each of the one or more apertures is in a range of about 2 mm to about 10 mm.

In some examples, at least one of the one or more apertures provides a circuitous path through a thickness of the baffle.

In some examples, the aperture is defined as a spacing between a plurality of baffle structures.

In another example, aspects of the present disclosure are directed toward an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle within the crystal growth chamber and spaced apart from the source material, wherein the baffle comprises a composite shaped structure.

In some examples, the baffle includes a convex surface, the convex surface being closest to the seed crystal.

In some examples, the baffle includes a convex surface, the convex surface being closest to the source material.

In some examples, the baffle includes a plurality of linear portions intersecting in at least one peak.

In some examples, the at least one peak is closer to the seed crystal relative to the source material.

In some examples, the at least one peak is closer to the source material relative to the seed crystal.

In some examples, the baffle has a trapezoid cross-section having a first surface with a long dimension and a second surface opposite the first surface with a short dimension.

In some examples, the first surface is closer to the seed crystal relative to the source material.

In some examples, the first surface is closer to the source material relative to the seed crystal.

In some examples, the baffle includes one or more recessed cavities.

In some examples, the baffle includes one or more apertures.

In some examples, the baffle includes graphite.

In some examples, the baffle includes a coating on the graphite.

In some examples, the coating is a pyrolytic coating.

In some examples, the coating includes tantalum carbide.

In some examples, the baffle has a porosity in a range of about 70% to about 97%.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle within the crystal growth chamber and spaced apart from the source material. The baffle has a shape configured to provide asymmetric vapor transport from the source material to the silicon carbide seed crystal.

In some examples, a silicon carbide vapor is transported through a first portion of the baffle at a first rate and is transported through a second portion of the baffle at a second rate. The first rate is different than the second rate.

In some examples, the first portion at least partially overlaps a central portion of the seed crystal and the second portion at least partially overlaps a central portion of the seed crystal.

In some examples, the first portion includes one or more apertures and the second portion does not include any apertures.

In some examples, the first portion includes one or more apertures having a first size and the second portion includes one or more apertures having a second size. The first size is different from the second size.

In some examples, the first portion includes a first set of apertures having a first density and the second portion includes a second set of apertures having a second density. The first density is different than the second density.

In some examples, the baffle includes graphite.

In some examples, the baffle includes a coating on the graphite.

In some examples, the coating is a pyrolytic coating.

In some examples, the coating includes tantalum carbide.

In some examples, the baffle has a porosity in a range of about 70% to about 97%.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle including one or more tubular structures within the crystal growth chamber and spaced apart from the source material.

In some examples, the tubular baffle has a sidewall that is non-perpendicular to the growth surface.

In some examples, the tubular baffle has a sidewall this is perpendicular to the growth surface.

In some examples, the sidewall is angled toward a central portion of the seed crystal.

In some examples, the sidewall is angled toward a peripheral portion of the seed crystal.

In some examples, the one or more tubular structures include a plurality of tubular structures.

In some examples, the tubular structures are arranged concentrically with one another.

In some examples, the crystal growth system further includes a baffle plate.

In some examples, the baffle plate includes one or more apertures.

In some examples, the baffle plate does not include any apertures.

In some examples, the tubular baffle includes graphite.

In some examples, the tubular baffle includes a coating on the graphite.

In some examples, the coating is a pyrolytic coating.

In some examples, the coating includes tantalum carbide.

In some examples, the tubular baffle has a porosity in a range of about 70% to about 97%.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle within the crystal growth chamber and spaced apart from the source material. The baffle includes a first baffle structure and a second baffle structure spaced apart from the first baffle structure.

In some examples, the first baffle structure and the second baffle structure define an opening for vapor transport.

In some examples, the first baffle structure includes one or more apertures and the second baffle structure includes no apertures.

In some examples, the first baffle structure includes a first aperture and the second baffle structure includes a second aperture.

In some examples, the first aperture is aligned with the second aperture.

In some examples, the first aperture is not aligned with the second aperture.

In some examples, the first baffle structure and the second baffle structure define an opening with a circuitous path for vapor transport.

In some examples, the second baffle structure includes a secondary source material.

In some examples, the system further includes a third baffle structure.

In some examples, the second baffle structure is between the first baffle structure and the third baffle structure.

In some examples, the first baffle structure has a first shape and the second baffle structure has a second shape that is different from the first shape.

In some examples, the first shape is a composite shape.

In some examples, the first baffle structure includes one or more recessed cavities and the second baffle structure includes one or more apertures.

In some examples, the first baffle structure includes a first aperture overlapping a central portion of the seed crystal and the second baffle structure includes a second aperture overlapping a peripheral portion of the seed crystal.

In some examples, one or more of the first baffle structure or the second baffle structure includes graphite.

In some examples, one or more of the first baffle structure or the second baffle structure includes a coating on the graphite.

In some examples, the coating is a pyrolytic coating.

In some examples, the coating includes tantalum carbide.

In some examples, one or more of the first baffle structure or the second baffle structure has a porosity in a range of about 70% to about 97%.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle within the crystal growth chamber and spaced apart from the source material. The baffle includes one or more recessed cavities.

In some examples, the one or more recessed cavities are on a surface of the baffle are closest to the seed crystal.

In some examples, the one or more recessed cavities are on a surface of the baffle are closest to the source material.

In some examples, the one or more recessed cavities overlap a central portion of the seed crystal.

In some examples, the one or more recessed cavities overlap a peripheral portion of the seed crystal.

In some examples, the baffle includes graphite.

In some examples, the baffle includes a coating on the graphite.

In some examples, the coating is a pyrolytic coating.

In some examples, the coating includes tantalum carbide.

In some examples, the baffle has a porosity in a range of about 70% to about 97%.

In an aspect, the present disclosure provides an example crystal growth system for growing silicon carbide crystalline material. The system includes a seed holder configured to hold a silicon carbide seed crystal. The seed crystal provides a growth surface for growth of the silicon carbide crystalline material. The system includes a crucible at least partially defining a crystal growth chamber. The system includes a source material. The system includes a baffle in a vapor transport path between the source material and the seed crystal and spaced apart from the source material. The baffle is, at least in part, graphite. At least a portion of the baffle has a porosity of about 70% or greater.

In some examples, the baffle has a porosity of about 80% or greater.

In some examples, the baffle has a porosity in a range of about 70% to about 97%.

In some examples, the baffle has a first portion having a first porosity and a second portion having a second porosity. The first porosity is different from the second porosity.

In some examples, the baffle includes a coating on the graphite.

In some examples, the coating is a pyrolytic coating.

In some examples, the coating includes tantalum carbide.

In some examples, the baffle includes one or more apertures.

In some examples, the baffle includes a plurality of baffle plates.

In some examples, the baffle has a composite shape.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A crystal growth system for growing crystalline material, the crystalline material comprising silicon carbide, the system comprising:
a seed holder configured to hold a silicon carbide seed crystal, the seed crystal providing a growth surface for growth of the silicon carbide crystalline material;
a crucible at least partially defining a crystal growth chamber;
a source material;
one or more baffles within the crystal growth chamber and spaced apart from the source material, the one or more baffles including one or more apertures defined through the one or more baffles,
wherein the baffle comprises a long dimension that is non-perpendicular to the growth surface of the seed crystal.

2. The crystal growth system of claim 1, wherein each of the one or more apertures has a width that is less than about 20% of a width of the crystal growth chamber.

3. The crystal growth system of claim 1, wherein each of the one or more apertures provides a path through the baffle for transport of vapor from the source material to the seed crystal without having significant crystal growth formation in the aperture.

4. The crystal growth system of claim 1, wherein each of the one or more apertures provides a thermal gradient in a direction along a thickness of the aperture.

5. The crystal growth system of claim 1, wherein a silicon carbide vapor is transported through a material of the baffle at a first rate and is transported through the one or more apertures at a second rate, wherein the first rate is different than the second rate.

6. The crystal growth system of claim 1, wherein the one or more apertures comprise a plurality of holes defined through the baffle.

7. The crystal growth system of claim 1, wherein the one or more apertures comprises an annular aperture defined through the baffle.

8. The crystal growth system of claim 1, wherein a vapor transport direction through the one or more apertures is in a non-perpendicular direction relative to the growth surface of the seed crystal.

9. The crystal growth system of claim 1, wherein the one or more apertures comprise a first aperture and a second aperture, wherein a width of the first aperture is different from a width of the second aperture.

10. The crystal growth system of claim 1, wherein the one or more apertures comprise a first plurality of apertures and a second plurality of apertures, wherein a density of the first plurality of apertures in the baffle is different from a density of the second plurality of apertures in the baffle.

11. The crystal growth system of claim 1, wherein the one or more apertures are arranged to transport vapor in a vapor transport direction that is more towards a central portion of the seed crystal relative to a peripheral portion of the seed crystal.

12. The crystal growth system of claim 1, wherein a thickness of the baffle is in a range of about 0.5 mm to about 25 mm.

13. The crystal growth system of claim 1, wherein a width of the baffle is at least 10 times greater than a thickness of the baffle.

14. The crystal growth system of claim 1, wherein the baffle comprises a plurality of baffle plates.

15. The crystal growth system of claim 1, wherein the baffle comprises graphite.

16. The crystal growth system of claim 15, wherein the baffle comprises a coating on the graphite.

17. The crystal growth system of claim 16, wherein the coating is a pyrolytic coating.

18. The crystal growth system of claim 16, wherein the coating comprises tantalum carbide.

19. The crystal growth system of claim 1, wherein the baffle has a porosity in a range of about 70% to about 97%.

20. A crystal growth system for growing silicon carbide crystalline material, comprising:
a seed holder configured to hold a silicon carbide seed crystal, the seed crystal providing a growth surface for growth of the silicon carbide crystalline material;
a crucible at least partially defining a crystal growth chamber;
a source material;
a baffle in a vapor transport path between the source material and the seed crystal and spaced apart from the source material, wherein the baffle comprises graphite, wherein at least a portion of the baffle has a porosity of about 70% or greater.
